(19) United States
(12) Patent Application Publication
(10) Pub. No.: US 2008/0042260 A1
(43) Pub. Date: Feb. 21, 2008

(54) MICRO-ELECTROMECHANICAL SYSTEMS DEVICE AND MANUFACTURING METHOD THEREOF

(76) Inventors: Heewon JEONG, Tokyo (JP); Hiroshi Fukuda, London (GB)

Correspondence Address: MILES & STOCKBRIDGE PC, 1751 PINNACLE DRIVE, SUITE 500, MCLEAN, VA, 22102-3833, US

(21) Appl. No.: 11/774,526

(22) Filed: Jul. 6, 2007

(30) Foreign Application Priority Data
Aug. 21, 2006 (JP) 2006-224179

(51) Int. Cl. H01L 23/12; H01L 21/00

(52) U.S. Cl. 257/704; 438/125; 257/E23.005; 257/E21.001

(57) ABSTRACT

A method of sealing and leading out an electrode for an MEMS device such as an angular velocity sensor, an acceleration sensor, or a combined sensor is provided. A fixed portion is formed within a device forming region surrounded with a base support, a beam is connected to the fixed portion, and a movable portion is connected to the beam. Further, a detection portion for detecting the displacement of the movable portion is disposed within the device forming region. An interconnection is connected to the movable portion and the detection portion, and the interconnection extends from the hermetically sealed device forming region to the external region at the outside. The interconnection penetrates the base support and is connected with the terminal. A hole is formed between the interconnection and the base support, and an insulating film is formed in the hole. The interconnection and the base support are insulated by an insulating film buried in the hole.

### CLAIM OF PRIORITY

The present application claims priority from Japanese Application JP 2006-224179 filed on Aug. 21, 2006, the content of which is hereby incorporated by reference into this application

### FIELD OF THE INVENTION

The present invention concerns an MEMS (Microelectro Mechanical Systems) having a function, for example, of an acceleration sensor, an angular velocity sensor, an oscillator, and a mechanical filter, as well as a manufacturing method thereof and it relates to a hermetically sealed MEMS device for transmitting and receiving electric signals to and from the outside, as well as a manufacturing technique thereof.

### BACKGROUND OF THE INVENTION

FIG. 41 shows an example of a sealing technique and an electrode leading technique of an existent MEMS device. In the technique, an MEMS structural portion 501, a beam 502, an electrode support 503 and an outer peripheral wall 504 formed so as to surround the electrode support 503 and the MEMS structural portion 501 are formed to a substrate. Caps 505 are bonded by anodic bonding above and below them, and signals can be transmitted and receiving to and from the outside by forming and fabricating a conductive film 507 after aperturing a through hole 506 to the cap 505 made of glass by sand blasting or the like.

In the technique known so far, for example, based on the specification of JP-A No. 10(1998)-213441 (Patent Document 1), a through via hole is formed in the upper cap, and the MEMS structural portion and a wiring pattern, etc. of an external circuit substrate are electrically connected by using a conductive paste (or metal) filled in the through via hole.

In the technique known so far, for example, based on the specification of JP-A No. 2000-186931 (Patent Document 2), a through via hole is formed to an angular velocity detection portion (MEMS structural portion) and a cap and then a pad is formed by depositing a conductive film thereon and patterning the same thereby transmitting and receiving signals to and from the outside.

Further, in the prior art known so far, for example, “Embedded Interconnect and Electrical Isolation for High-Aspect-Ratio, SOI Inertial Instruments”, Transducers' 97, pp. 637-640 (Non-Patent Document 1), a peripheral circuit is formed in hybridization with an MEMS device to an active layer of an SOI (Silicon On Insulator) wafer, and an isolation trench is formed between the MEMS device portion and the peripheral circuit for electrical insulation. Further, signals are transmitted and received between the peripheral circuit portion and the MEMS device portion by aerial wirings overriding the isolation trench.

### SUMMARY OF THE INVENTION

By the way, in the prior art described above, the caps 505 are bonded to the both surfaces of the layer formed with the MEMS structural portion 501 and the outer peripheral wall 504 formed so as to surround the MEMS structural portion 501. Further, after bonding the cap 505, the through holes 506 are apertured by the number of the electrodes using sand blasting or the like. Then, the electrodes are formed by depositing or burying conductors such as a conductive film or a conductive paste to connect the MEMS structural portion 501 and the outside.

Therefore, micro-cracks tend to occur at the bonded surface due to the effect of stresses upon fabrication of the through holes 506 to cause a possibility for the aging change of circumstance surrounding the MEMS structural portion 501 such as sealing pressure.

Further, the through hole 506 formed by the sand blasting has a larger diameter at the surface of the cap 505 where fabrication is started and smaller diameter at the bottom face thereof. Accordingly, it is necessary to define the pitch between the through holes 506 corresponding to the hole diameter formed at the surface, which is disadvantages for the reduction of size.

Particularly, in an angular velocity sensor, acceleration sensor, a combined sensor capable of measuring various physical amounts such as angular velocity or acceleration simultaneously, the number of necessary electrodes increases to bring about a problem that the size reduction of the sensor is limited by the size of the electrode.

Further, since the plurality of electrode supports 503 are isolated from each other in view of the plane, the outer peripheral wall 504 of a shape surrounding the MEMS structural portion 501, the beam 502, and the electrode support 503 is indispensable for air tight sealing, which is disadvantageous for the size reduction of the device.

Further, when the through hole 506 is fabricated to the cap 505 by sand blasting or the like, a discontinuous edge is formed at the bonded surface between the cap 505 and the substrate and possibly cause a worry of disconnecting the conductive film to result in a problem of worsening the yield.

Further, since the sand blasting is a fabrication method conducted by using small abrasion grains such as sands and it is impossible for consecutive treatment in a clean room in view of the problem, for example, dusting. Accordingly, consecutive fabrication in the clean room is impossible to result in a worry such as lowering of the yield and lowering of the working efficiency.

Further, according to the content of the Non-Patent Document 1, while the MEMS device portion and the peripheral circuit are formed in hybridization to the active layer of the SOI wafer and they are electrically isolated from each other by an isolation trench, the document does not mention to the sealing at the wafer level and a particular consideration is necessary for protecting the MEMS device portion upon dicing of chips.

In view of the above, the present invention has been accomplished for the problems involved in the prior art described above and intends to provide a method of sealing an MEMS device and a method of leading out electrodes, for example, in an angular velocity sensor, an acceleration sensor or a combined sensor.

The foregoing as well as other objects and novel features of the invention will become apparent with reference to the description of the present specification and the appended drawings.

Among inventions disclosed in the present application, the outline of typical inventions is briefly described as below.

A micro-electromechanical systems device according to the invention includes (a) a semiconductor substrate, (b) a base support fixed to the semiconductor substrate and formed so as to surround a predetermined region, (c) a fixed portion fixed to the semiconductor substrate and formed within the predetermined region, (d) a beam connected to the fixed portion and formed within the predetermined region, (e) a movable portion connected to the beam and suspended in the space within the predetermined region, (f) a terminal formed to the outside of the predetermined region surrounded with the base support, (g) a interconnection for connecting the movable portion and terminal through the base support, (h) a base formed on the base support and the interconnection and formed so as to surround the predetermined portion and (i) a cap formed on the base and covering the predetermined region, in which an insulating film is formed between the base support and the interconnection and between the interconnection and the base.

Further, a method of manufacturing a micro-electromechanical systems device according to the invention includes: (a) a step of providing a semiconductor substrate containing a support substrate, an intermediate insulative layer formed on the support substrate, and a conductor layer formed on the intermediate insulative layer, (b) a step of forming a hole reaching the intermediate insulative layer to the conductor layer, (c) a step of burying a first insulating film in the hole, (d) a step of forming a first conductor film on the conductor layer, (e) a step of patterning the first conductor film thereby forming a terminal to the outside of a predetermined region, (f) a step of forming a second insulating film on the conductor layer,

(g) a step of forming a second conductor film on the second insulating film, (h) a step of patterning the second insulating film and the second conductor film thereby forming a base for opening the predetermined region and the terminal, (i) a step of patterning the conductor layer exposed to the predetermined region and the terminal, thereby forming a base support surrounding the predetermined region and formed with the base thereon by way of the second insulating film, forming a fixed portion in the predetermined region and further forming a beam connected to the fixed portion and formed within the predetermined region, a movable portion connected with the beam and formed within the predetermined region, and a interconnection for connecting the movable portion and the terminal, in which the first insulating film is formed between the interconnection penetrating through the base support and the base support, and the second insulating film is formed between the interconnection penetrating the base support and the base, (j) a step of removing the intermediate insulative layer formed in the underlayer of the beam and the movable portion thereby suspending the movable portion in the space within the predetermined region, and (k) a step of bonding the base and the cap to seal the predetermined region.

Further, a method of manufacturing a micro-electromechanical systems device according to the invention includes (a) a step of providing a semiconductor substrate containing a support substrate, an intermediate insulative layer formed on the support substrate, and a conductor layer formed on the intermediate insulative layer, (b) a step of patterning the conductor layer thereby forming a base support surrounding a predetermined region, a fixed portion formed within the predetermined region, a beam connected to the fixed portion and formed within the predetermined region, a movable portion connected to the beam and formed within the predetermined region and an interconnection penetrating the base support from the predetermined region and extending to the outside, (c) a step of forming a third insulating film so as to bury the patterned conductor layer and forming the third insulative layer to the periphery of the interconnection penetrating the base support, (d) a step of forming a terminal on the conductor film present to the outside of the predetermined region and connecting the terminal and the interconnection, (e) a step of forming a base on the base support by way of the third insulating film, (f) a step of removing the third insulating film within the predetermined region and the intermediate insulating film formed in the under layer of the beam and the movable portion thereby suspending the movable portion in the space within the predetermined region, and (g) a step of bonding the base and the cap thereby sealing the predetermined region.

Among the inventions disclosed in the present application, effects obtained by typical inventions are to be described briefly as below.

Since the electrode for external connection is formed to the outside of a hermetically sealed predetermined region, and the predetermined region is sealed by using a cap having an opening above the electrode for external connection, it is not necessary for aperturing fabrication to the cap after bonding for leading out the electrode. Therefore, micro-cracks are not generated to the bonded surface and the sealing performance can be improved. As a result, it is possible to manufacture an MEMS device of high performance and high reliability of less aging change such as pressure fluctuation.

### BRIEF DESCRIPTION OF THE DRAWINGS

Preferred embodiments of the present invention will be described in details based on the drawings, wherein

FIG. 1 is a plan view showing the constitution of an MEMS device in a first embodiment of the invention;

FIG. 2 is a cross sectional view showing a cross section of FIG. 1 taken along line A-A′;

FIG. 3 is a cross sectional view showing a cross section of FIG. 1 taken along line B-B′;

FIG. 4 is a cross sectional view showing a cross section of FIG. 1 taken along line C-C′;

FIG. 5 is a plan view showing the steps of manufacturing an MEMS device in the first embodiment;

FIG. 6 is a plan view for explaining a manufacturing step for a cross section of FIG. 5 taken along line D-D′;

FIG. 7 is a cross sectional view showing the steps of manufacturing the MEMS device succeeding to FIG. 6;

FIG. 8 is a cross sectional view showing the steps of manufacturing the MEMS device succeeding to FIG. 7;

FIG. 9 is a plan view showing the steps of manufacturing the MEMS device in the first embodiment;

FIG. 10 is a plan view for explaining a manufacturing step for a cross section of FIG. 9 taken along line E-E′;

FIG. 11 is a cross sectional view showing a step of manufacturing the MEMS device succeeding to FIG. 10;

FIG. 12 is a cross sectional view showing the step of manufacturing the MEMS device succeeding to FIG. 11;

FIG. 13 is a plan view showing the constitution of the MEMS device in the first embodiment;

FIG. 14 is a cross sectional view for explaining a manufacturing step for a cross section of FIG. 13 taken along line F-F′;

FIG. 15 is a cross sectional view showing a step of manufacturing the MEMS device succeeding to FIG. 14;

FIG. 16 is a plan view showing the constitution of the MEMS device in the first embodiment;

FIG. 17 is a cross sectional view for explaining a manufacturing step for a cross section of FIG. 16 taken along line G-G′;

FIG. 18 is a plan view showing the constitution of the MEMS device in the first embodiment;

FIG. 19 is a perspective view showing a constitution of an MEMS device in a second embodiment;

FIG. 20 is a cross sectional view showing a cross section of FIG. 19 taken along line y1-y1;

FIG. 21 is a cross sectional view showing a cross section of FIG. 19 taken along line y2-y2;

FIG. 22 is a plan view showing a constitution of the MEMS device in the second embodiment;

FIG. 23 is a cross sectional view for explaining a manufacturing step for a cross section of FIG. 22 taken along line x1-x1;

FIG. 24 is a cross sectional view showing a step of manufacturing the MEMS device succeeding to FIG. 23;

FIG. 25 is an enlarged cross sectional view for a portion of FIG. 24;

FIG. 26 is a plan cross sectional view for explaining a manufacturing step for a cross section of FIG. 22 taken along line y2-y2;

FIG. 27 is a cross sectional view showing another example of a manufacturing step in the manufacturing step shown in FIG. 25;

FIG. 28 is a cross sectional view showing a step of manufacturing the MEMS device succeeding to FIG. 26;

FIG. 29 is a cross sectional view showing a step of manufacturing the MEMS device succeeding to FIG. 28;

FIG. 30 is a cross sectional view showing a step of manufacturing the MEMS device succeeding to FIG. 29;

FIG. 31 is a cross sectional view showing an example of mounting the MEMS device in the second embodiment;

FIG. 32 is a cross sectional view showing a constitution of an MEMS device in a third embodiment;

FIG. 33 is a cross sectional view showing a manufacturing step of the MEMS device succeeding to FIG. 32;

FIG. 34 is a cross sectional view showing a manufacturing step of the MEMS device succeeding to FIG. 33;

FIG. 35 is a cross sectional view showing a manufacturing step of the MEMS device succeeding to FIG. 34;

FIG. 36 is a cross sectional view showing a step of manufacturing the MEMS device succeeding to FIG. 35;

FIG. 37 is a cross sectional view showing a step of manufacturing the MEMS device succeeding to FIG. 36;

FIG. 38 is a cross sectional view showing an MEMS device in a fourth embodiment;

FIG. 39 is a plan view showing the constitution of an MEMS device in a fifth embodiment;

FIG. 40 is a cross sectional view showing a cross section of FIG. 39 taken along line x2-x2; and

FIG. 41 is a cross sectional view showing the technique studied by the present inventors.

### DETAILED DESCRIPTION OF THE PREFERRED EMBODIMENTS

In the following preferred embodiments, description is to be made while being divided into plural sections or embodiments if it is necessary for the sake of convenience but they are not irrelevant to each other but in such a relation that one is a modified example, details, supplementary description, etc. to a portion or the entirely of other except for a case specified particularly.

Further, in the following embodiments, in a case where the number of elements, etc. (including number, numerical value, amount, range, etc.) are referred to, they are not restricted to the specified number but may be more than or less than the specified number except for the case specified particularly or a case apparently restricted to a specified number in view of the principle.

Further, in the following embodiments, the constitutional elements (also including elemental steps, etc.) are not always essential except for a case specified particularly and a case apparently considered to be essential in view of the principle.

In the same manner, in the following embodiments, when the shape, positional relationship, etc. are referred to for the constitutional elements, it is assumed that they substantially include those approximate or similar to the shapes, etc. thereof except for a case specified particularly or a case which is considered apparently not so in view of the principle.

Further, throughout the drawings for describing the embodiment, an identical member carry an identical reference in principle for which duplicate descriptions are to be omitted. Further, even a plan view may sometimes be applied with hatching for the sake of easy understanding of the drawings.

### First Embodiment

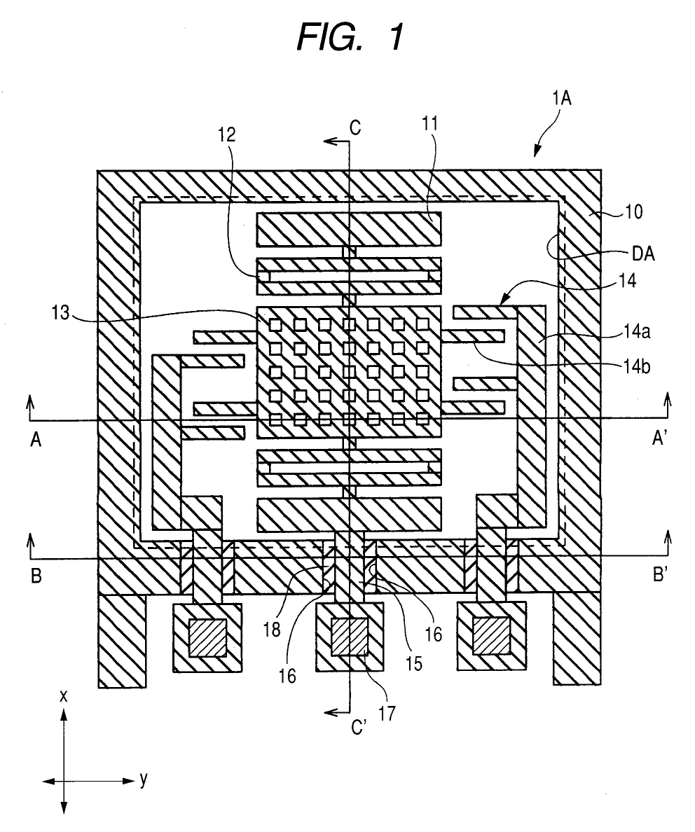

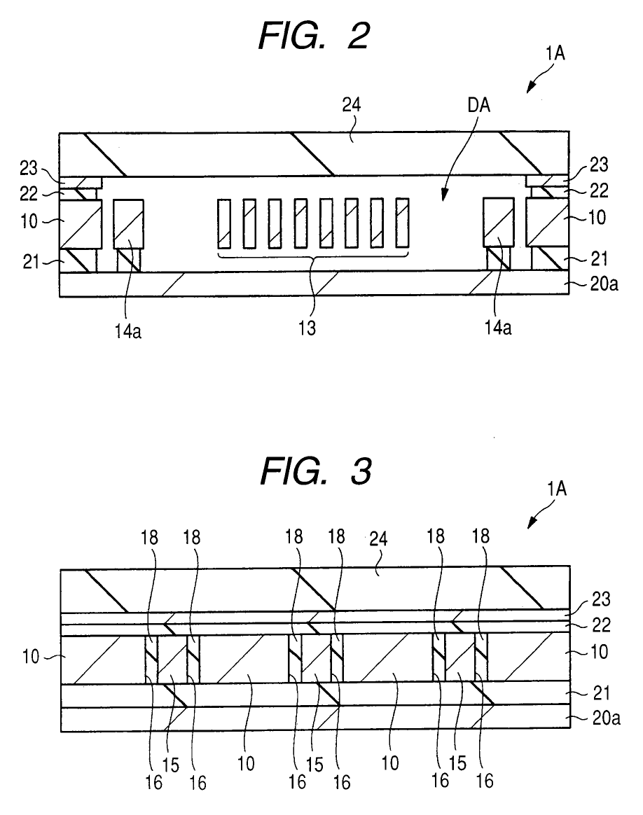

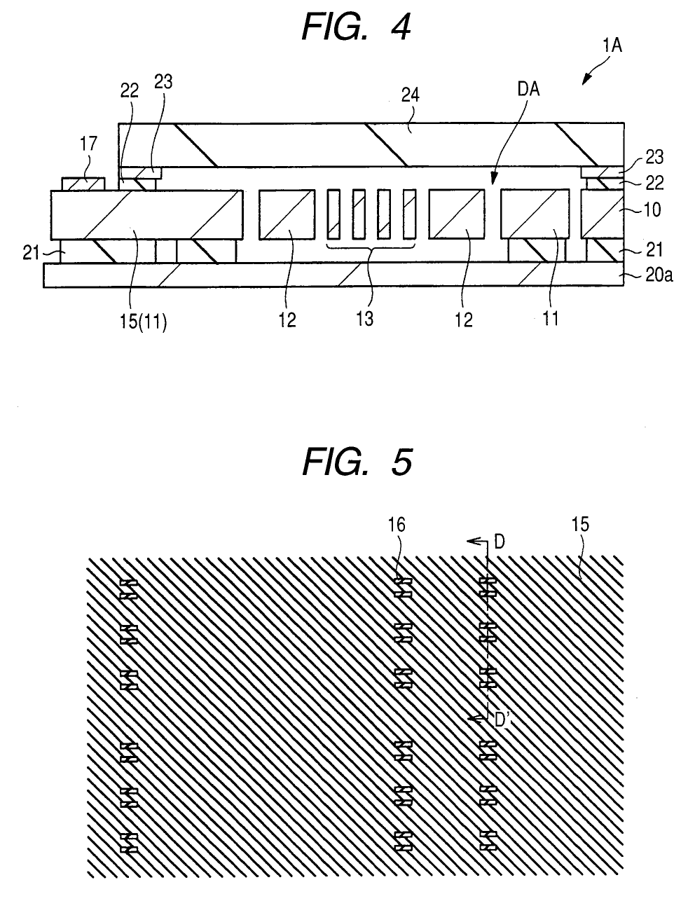

A micro-electromechanical systems device (hereinafter referred to as an MEMS device) of a first embodiment is to be described with reference to the drawings. In the first embodiment, description is to be made for an acceleration sensor as an example of the MEMS device. FIG. 1 is a schematic view showing main constituent elements of an acceleration sensor in the first embodiment in view of a plane. FIG. 2 shows a cross section of FIG. 1 along line A-A′, FIG. 3 shows a cross section of FIG. 1 along line B-B′, and further FIG. 4 shows a cross section of FIG. 1 along line C-C′.

In FIG. 1, a base support 10 is formed so as to surround a device forming region (predetermined region) DA in an MEMS device 1A. While a base and a cap covering the device forming region DA by bonding with the base are formed above the base support 10, the base and the cap are not illustrated in FIG. 1. Since the constitution for the base and the cap are illustrated in FIG. 2 to FIG. 4, they are described with reference to FIG. 2 to FIG. 4.

A fixed portion 11 is formed within the device forming region DA surrounded with the base support 10. The fixed portion 11 is fixed to the semiconductor substrate in the lower layer. Then, an elastically deformable beam 12 is connected with the fixed portion 11. A movable portion 13 is connected with the elastically deformable beam 12. That is, the movable portion 13 as a main portion of an acceleration sensor is formed at the central part of the device forming region DA surrounded with the base support 10, and the fixed portions 11 are formed so as to sandwich the movable portion 13 on both sides thereof. Then, it is connected with the fixed portion 11 formed so as to sandwich the movable portion 13 by way of the elastically movable beam 12 respectively. The movable portion 13 is suspended in the space within the device forming region DA and constituted so as to be displaceable.

Further, a detection portion 14 for detecting the displacement of the movable portion 13 is formed within the device forming region DA. The detection portion 14 is formed of a capacitance element having electrodes disposed in a comb-shape. Specifically, it comprises a fixed electrode 14a fixed to the semiconductor substrate and a movable electrode 14b integrated with the movable portion 13, fixed respectively in the device forming region DA.

The movable portion 13 including the movable electrode 14b is connected electrically with a terminal 17 formed to the outside of the device forming region DA by way of an interconnection 15. The terminal 17 is an electrode for use in external connection. That is, the terminal 17 is disposed so as to output electric signals generated within the device forming region DA to an external integrated circuit. In this case, the beam 12 and the fixed portion 11 are utilized as a portion of the wiring. The device forming region DA is hermetically sealed, and the interconnection 15 is constituted so as to penetrate the base support 10 disposed so as to surround the device forming region DA for connecting the movable portion 13 in the sealed device forming region DA and the terminal 17 formed to the outside of the device forming region DA. That is, the interconnection 15 is formed in the base support 10 for connecting the device forming region DA and the external region, and the interconnection 15 extends from the device region DA to the external region.

The interconnection 15 is formed in the base support 10, a hole 16 is formed between the interconnection 15 and the base support 10, and an insulating film 18 is formed so as to bury the hole 16. The insulating film 18 prevents electrical contact with the interconnection 15 and the base support 10. That is, since the interconnection 15 and the base support 10 are formed, for example, of a polysilicon film, the interconnection 15 and the base support 10 are conducted when they are in contact with each other. As shown in FIG. 1, a plurality of interconnections 15 each of different destination for connection are formed in the base support 10. Therefore, when the interconnection 15 and the base support 10 are conducted, a plurality of interconnections 15 are short-circuit to each other. Then, the insulating film 18 is formed to the inside of the hole 16 disposed between the base support 10 and the interconnection 15 so as to avoid conduction between the interconnection 15 and the base support 10. Further, while the hole 16 is formed between the interconnection 15 and the base support 10, in a case where a gap is present due to the hole 16, the device forming region DA can not be sealed hermetically. Accordingly, the insulating film 18 has a function of not electrically connecting the interconnection 15 and the base support 10 and also has a function of burying the hole 16 so as not to form the gap.

Then, FIG. 2 is a cross sectional view showing a cross section of FIG. 1 taken along line A-A′. In FIG. 2, an SOI (Silicon On Insulator) substrate is used, for example, as a semiconductor substrate constituting the MEMS device 1A in the first embodiment. That is, in the SOI substrate, an intermediate insulative layer 21 is formed on a support substrate 20a, and a conductor layer (active layer) is formed on the intermediate insulative layer 21. The support substrate 20a is formed, for example, of silicon (Si), and the intermediate insulative layer 21 is formed, for example, of silicon oxide (SiO₂). Further, the conductor layer formed on the intermediate insulative layer 21 is formed, for example, of conductive silicon.

The total thickness of the support substrate 20a and the intermediate insulative layer 21 is, for example, from several tens to several hundreds μm and the thickness of the conductor layer is, for example, from several to several tens μm. In the first embodiment, while the SOI substrate is used, the semiconductor substrate is not restricted to the SOI substrate but can be changed variously. For example, a conductive polysilicon using the MEMS technique or a plating metal such as nickel (Ni) may also be used as the conductor layer.

As shown in FIG. 2, the intermediate insulative layer 21 is formed on the support substrate 20a and the conductor layer is formed on the intermediate insulative layer 21. The base support 10, the fixed electrode 14a of the detection portion, and the movable portion 13 are formed by fabricating the conductor layer. That is, the base support 10, the fixed electrode 14a, and the movable portion 13 are formed by patterning an identical conductor layer formed on the intermediate insulative layer 21. Although not illustrated in FIG. 2, the fixed portion 11, the beam 12, the movable electrode 14b, and the interconnection 15 shown in FIG. 1 are also formed by patterning the identical conductor layer. The base support 10, the fixed portion 11 (not illustrated in FIG. 2), the fixed electrode 14a, and the interconnection 15 (not illustrated in FIG. 2) formed of the conductor layer are fixed by way of the intermediate insulative layer 21 formed in the lower layer to the support substrate 20a. On the other hand, the intermediate layer 21 formed below the movable portion 13, the movable electrode 14b (not illustrated in FIG. 2) and the beam 12 (not illustrated in FIG. 2) are removed to render them in a state suspended in the space. Accordingly, the movable portion 13, etc. are constituted such that they can move within a plane parallel to the main surface (device forming surface) of the SOI substrate (support substrate 20a).

An insulating film 22 is formed on the base support 10, and a base 23 is formed on the insulating film 22. The insulating film 22 is formed, for example, of a silicon oxide film, and the base 23 is formed, for example, of a polysilicon film. A cap 24 is formed on the base 23, and the cap 24 is disposed so as to cover the device forming region DA of the MEMS device 1A. The cap 24 is formed, for example, of a glass substrate and bonded with the base 23 made of a polysilicon film by anodic bonding.

Then, FIG. 3 is a cross sectional view showing a cross section of FIG. 1 along line B-B′. As shown in FIG. 3, the intermediate insulative layer 21 is formed on the support substrate 20a, and the base support 10 formed by patterning the conductor layer is disposed on the intermediate insulative layer 21. The interconnection 15 is formed in the base support 10 and the interconnection 15 penetrates the base support 10. That is, as shown in FIG. 1, the interconnection 15 extends from the device forming region DA surrounded with the base support 10 to the external region at the outside of the device forming region DA, and the interconnection 15 crosses the base support 10 in the course of extending to the external region. The cross section at the crossing region is shown in FIG. 3.

A hole 16 reaching the intermediate insulative layer 21 is disposed between the interconnection 15 and the base support 10 crossing to each other to prevent direct connection between the interconnection 15 and the base support 10. Then, the insulating film 18 is buried to the inside of the hole 16. Further, the insulating film 22 is formed on the base support 10, the interconnection 15, and the insulating film 18, and the base 23 is formed on the insulating film 22. In this case, it may also be considered to form the base 23 directly on the base support 10, the interconnection 15, and the insulating film 18, but this results in the following disadvantage. That is, the hole 16 is formed between the base support 10 and the interconnection 15 for preventing the plurality of interconnections 15 disposed in the base support 10 from conducting to each other, and the insulating film 18 is buried to the inside of the hole 16. Accordingly, this can avoid conduction of the plurality of interconnections 15 from conducting to each other by way of the base support 10. However, when the base 23 is formed directly on the base support 10, the interconnection 15, and the insulating film 18, the plurality of interconnections 15 are connected by way of the base 23. The base 23 is formed of a conductive polysilicon film since it is anodically bonded relative to the cap 24. Therefore, the plurality of interconnections 15 are electrically connected by way of the base 23. Then, in the first embodiment, the base 23 is not formed directly on the base support 10, the interconnection 15, and the insulating film 18, but the insulating film 22 is formed and then the base 23 is formed on the insulating film 22. This can prevent the plurality of interconnections 15 from electrical connection by way of the base 23. As described above, a countermeasure for suppressing the occurrence of short-circuit between the plurality of interconnections 15 is adapted for the crossing region between the interconnection 15 and the base support 10, by forming the insulating film so as to cover the periphery of the interconnection 15.

Then, FIG. 4 is a cross sectional view showing a cross section of FIG. 1 along line C-C′. As shown in FIG. 4, the intermediate insulative layer 21 is formed on the support substrate 20a, and the conductor layer of the SOI substrate is formed on the intermediate insulative layer 21. The conductor layer is patterned to form the base support 10, the fixed portion 11, the beam 12, the movable portion 13, and the interconnection 15. That is, the base support 10, the fixed portion 11, the beam 12, the movable portion 13, and the interconnection 15 are formed by fabricating an identical conductor layer. Then, the intermediate insulative layer 21 is formed in the layer below the base support 10 and the fixed portion 11 and fixed by way of the intermediate insulative layer 21 to the support substrate 20a. On the other hand, the intermediate layer 21 formed in the lower layer below the beam 12 and the movable portion 13 is removed, so that the beam 12 and the movable portion 13 are suspended in the space within the device forming region DA.

Successively, the base 23 is formed above the base support 10 and the interconnection 15 by way of the insulating film 22, the base 23 and the cap 24 are bonded by anodic bonding, and the device forming region DA of the MEMS device 1A is covered by the cap 24. That is, the device forming region DA of the MEMS device 1A is hermetically sealed by the cap 24 which is anodically bonded to the base 23. The interconnection 15 is formed so as to extend from sealed device forming region DA to the external region, and the interconnection 15 is connected to the terminal 17 formed to the not sealed external region. In the first embodiment, the terminal 17 is not formed to the hermetically sealed device forming region DA but the terminal 17 is formed in the external region to the outside of the device forming region DA. Then, for electrical connection of the terminal 17 with the movable portion 13 within the device forming region DA, the interconnection 15 extends from the hermetically sealed device forming region DA to the external region. The cap 24 is formed above the terminal 17 formed in the external region. That is, an opening is formed in the cap 24 to open the portion above the terminal 17, such that the terminal 17 and the external integrated circuit can be connected by means of a wire or the like.

The MEMS device 1A in the first embodiment has been constituted as described above and, successively, the feature of the invention is to be described. At first, one of the features of the invention is that the terminal 17 for external connection is disposed in the external region to the outside of the hermetically sealed device forming region DA. With such a constitution, it is no more necessary to apply aperturing for forming the terminal to the cap 24 after attaching the cap 24. Accordingly, occurrence of micro-cracks to the bonded surface of the cap 24 can be suppressed to improve the airtightness. As a result, the MEMS device 1A of high performance and high reliability of less aging change such as fluctuation of the pressure can be formed.

For example, in FIG. 41 showing the technique studied by the present inventors, the MEMS structural portion 501, the beam 502, the electrode support portion 503, and the outer peripheral wall 504 formed so as to surround the MEMS structural portion 501 are formed to the substrate 500. Then, the cap 505 is bonded to the outer peripheral wall 504 by anodic bonding, and the through hole 506 is apertured to the cap 505 made of glass by sand blasting or the like and then the conductive film 507 is formed and fabricated to enable transmission and reception of signals to and from the outside.

However, in this technique, the cap 505 is bonded to both surfaces of the layer in which the MEMS structural portion 501 and the outer peripheral wall 504 formed so as to surround the MEMS structural portion 501 is formed. Then, after bonding the caps 505, through holes 506 by the number of electrodes are apertured by using sand blasting or the like. Then, the electrode is formed by depositing or burying the conductor such as the conductive film or the conductive paste to connect the MEMS structural portion 501 and the outside. Accordingly, micro-cracks tend to occur to the bonded surface due to the effect of stresses upon fabrication of the through hole 506 to result in a problem of aging change for the environment surrounding the MEMS structural portion 501 such as sealing pressure.

On the other hand, in the first embodiment, the terminal 17 for external connection is disposed in the external region to the outside of the hermetically sealed device forming region DA. Accordingly, aperturing fabrication for forming the terminal to the cap 24 after attaching the cap 24 is no more necessary. Therefore, occurrence of micro-cracks to the bonded surface of the cap 24 can be suppressed to improve airtightness. As a result, an MEMS device 1A of high performance and high reliability of less aging change such as fluctuation of pressure can be formed.

As described above, one of the features of the invention is to form the terminal 17 in the external region to the outside of the hermetically sealed device forming region DA. In this constitution, it is necessary to form the interconnection 15 for electrically connecting the structural member formed in the inside of the device forming region DA and the terminal 17 formed in the external region. In this case, since the base support 10 is formed so as to surround the device forming region DA, the base support 10 and the interconnection 15 cross to each other in a case of connecting the inside and the outside of the device forming region DA by the interconnection 15. Since the base support 10 and the interconnection 15 are formed, for example, of an identical conductor layer, they are short-circuited when crossed directly. That is, since the interconnections 15 led out to the external region are generally present in plurality, when the plurality of interconnections 15 penetrating the base support 10 are formed in a state in direct contact with the base support 10, the plurality of interconnections 15 are conducted to each other. Then, it is one of the features of the first embodiment that the hole 16 is disposed between the base support 10 and interconnection 15 as shown in FIG. 3 and the insulating film 18 is buried to the inside of the hole 16. Thus, the interconnection 15 and the base support 10 can be crossed while avoiding conduction between the base support 10 and the interconnection 15. That is, the interconnection 15 can be extended from the inside of the device forming region DA to the external region while ensuring the insulation property between the base support 10 and the interconnection 15. Further, even when the hole 16 is formed, since the inside of the hole 16 is buried with the insulating film 18, the hole 16 is not left as it is in the base support 10. Accordingly, the device forming region DA can be completely sealed hermetically. That is, by forming the insulating film 18 to the hole 16, the interconnection 15 can be extended from the inside of the device forming region DA to the external region while ensuring the insulative property between the base support 10 and the interconnection 15, and the device forming region DA can be sufficiently sealed hermetically.

Further, as shown in FIG. 3, the base 23 is formed above the base support 10, the interconnection 15, and the insulating film 18. The base 23 is constituted so as to be anodically bonded with the cap 24 formed on the base 23. Accordingly, the base 23 is formed, for example, of a polysilicon film, while the cap 24 is constituted, for example, of a glass substrate. As described above, since the base 23 is formed of the conductor film, when the base 23 is formed directly on the interconnection 15, the plurality of interconnections 15 are electrically connected with each other by way of the base 23. Then, the base 23 is formed by way of the insulating film 22 above the base support 10, the interconnection 15, and the insulating film 18. This is also one of the features of the invention. This can prevent short-circuit between the plurality of interconnections 15. From the foregoings, it can be seen that one of the features is that upper and lower and right and left sides (periphery) of the interconnection 15 are covered with the insulating film in the region where the base support 10 and the interconnection 15 are crossed.

Then, as shown in FIG. 4, it is one of the features of the invention that the cap 24 is not formed above the terminal 17 formed in the external region to the outside of the device forming region DA. That is, the cap 24 extends as far as a portion above the terminal 17, and an opening is formed previously to open the portion above the terminal 17. Thus, there is no requirement for aperturing fabrication for terminal connection to the cap 24 and the manufacturing steps of the MEMS device 1A can be simplified.

For example, in FIG. 41 showing the technique studied by the present inventors, it is difficult to form the cap 505 having the opening above the electrode support 503. This is because the electrode support 503 is disposed inside of the hermetically sealed device forming region, and the cap 505 should hermetically seal the device forming region. That is, in a case where an opening larger than the electrode support 503 is formed to the cap 505, the device forming region can no more be sealed hermetically.

On the contrary, in the first embodiment, the terminal 17 is disposed to the outside of the hermetically sealed device forming region. That is, the terminal 17 is formed in the external region where hermetic sealing is not necessary. Therefore, the opening can be formed to the cap 24 to open the portion above the terminal 17. As described above, in the first embodiment, since it is not necessary to form the terminal 17 for external connection by sand blasting, the yield for the production step can also be improved.

Since the fabrication by sand blasting is a fabrication method conducted by using fine abrasive grains such as sands, the treatment in the clean room is not possible in view of the problem such as dusting. Accordingly, no consecutive through fabrications in the clean room is possible to result in a worry such as lowering of the yield and lowering of the working efficiency.

On the contrary, in the first embodiment, since the aperturing step such as sand blasting is not necessary, the MEMS device 1A can be manufactured consecutively in the clean room thereby enabling to improve the yield in the manufacturing step and improve the working efficiency.

Further, in the MEMS device 1A of the first embodiment, as shown in FIG. 4, the intermediate insulative layer 21 is formed on the support substrate 20a, and the conductor layer is formed on the intermediate insulative layer 21. Then, the interconnection 15 is formed by patterning the conductor layer, and the terminal 17 is formed on the interconnection 15 in the external region to the outside of the device forming region DA. As described above, in the first embodiment, the terminal 17 can be formed, for example, by using a conductor film such as an aluminum film on the interconnection 15 made of the conductor layer. Accordingly, it can be connected with the wiring pattern of an external integrated circuit or a circuit substrate by the means such as wire bonding. Accordingly, compared with the technique of forming the electrode (terminal) by depositing the conductor film on the lateral surface of the through hole formed by the sand blasting fabrication, compatibility with the existent production step for the semiconductor device is higher and the connection reliability with the terminal 17 can be improved.

Then, the operation of the MEMS device 1A in the first embodiment is to be described. In FIG. 1, when acceleration is applied in the direction x, the beam 12 is elastically deformed and the movable portion 13 moves in the direction x. Thus, the movable electrode 14b of the detection portion 14 formed integrally with the movable portion 13 also moves (displaces) in the direction x. Therefore, the distance between the movable electrode 14b and the fixed electrode 14a of the detection portion 14 (direction x) changes. Accordingly, the static capacitance of the capacitor element constituted with the movable electrode 14b and the fixed electrode 14a changes. Acceleration can be measured by detecting the change of the static capacitance by the external electric circuit or the like. Since the movable electrode 14b and the fixed electrode 14a are connected respectively by way of the interconnections 15 to the terminal 17, change of the static capacitance between the movable electrode 14b and the fixed electrode 14a can be measured by electrically connecting the terminal 17 to an integrated circuit for a capacitance measurement separately from the MEMS device 1A. Further, an integrated circuit for measurement of the capacitance may be formed on one identical support substrate 20a with that for the MEMS device 1A and they may be electrically connected by using the terminal 17.

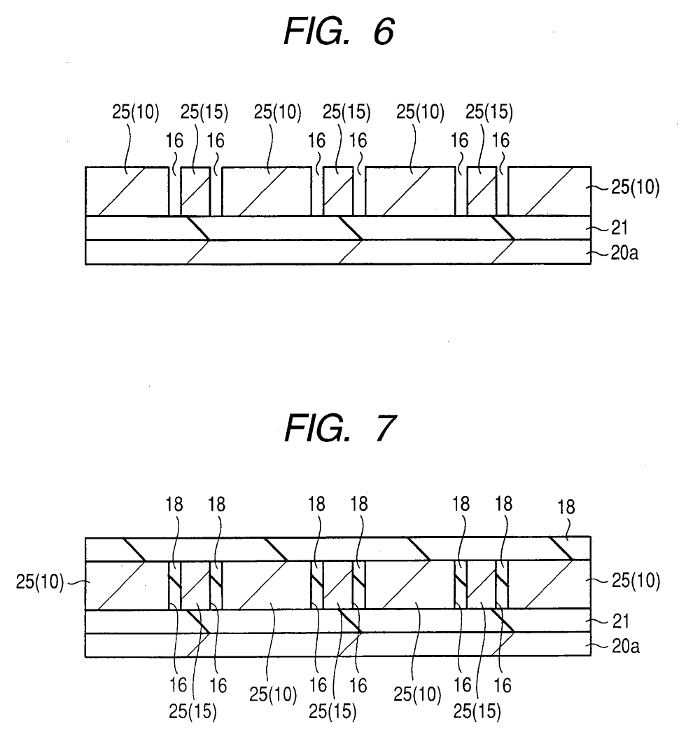

Successively, a method of manufacturing the MEMS device 1A in the first embodiment is to be described with reference to the drawings. At first, as shown in FIG. 5, holes 16 are formed to a conductor layer 25 of an SOI substrate by using photolithographic technique and etching technique. As shown in FIG. 3, the hole 16 is formed so as to electrically insulate the base support 10 and the interconnection 15 in the crossing region between the base support 10 and the interconnection 15 to be formed in the subsequent steps. A step of forming holes 16 and burying the insulating film 18 in the holes 16 is to be described with reference to the cross section taken along line D-D′ in FIG. 5 (FIG. 6 to FIG. 8).

As shown in FIG. 6, an SOI substrate in which an intermediate insulative layer 21 is formed on a support substrate 20a, and a conductor layer 25 is formed in the intermediate insulative layer 21 is provided. Then, the holes 16 are formed in the conductor layer 25 by utilizing the photolithographic technique and the etching technique. The hole 16 penetrates the conductor layer 25 and reaches the intermediate insulative layer 21 at the bottom. This can separate the base support 10 and the interconnection 15 formed by patterning the conductor layer 25 in the subsequent step in the crossing region.

Then, as shown in FIG. 7, an insulating film 18 is formed on the conductor layer 25 in which the holes 16 are formed. The insulating film 18 is formed, for example, of a silicon oxide film and can be formed, for example, by a CVD (Chemical Vapor Deposition) method. The insulating film 18 has a function of electrically insulating the base support 10 and the interconnection 15 to be formed in the step which is to be described later and also has a function of hermetically sealing the device forming region. By forming the insulating film 18 by the CVD method, a buried film of good airtightness can be formed.

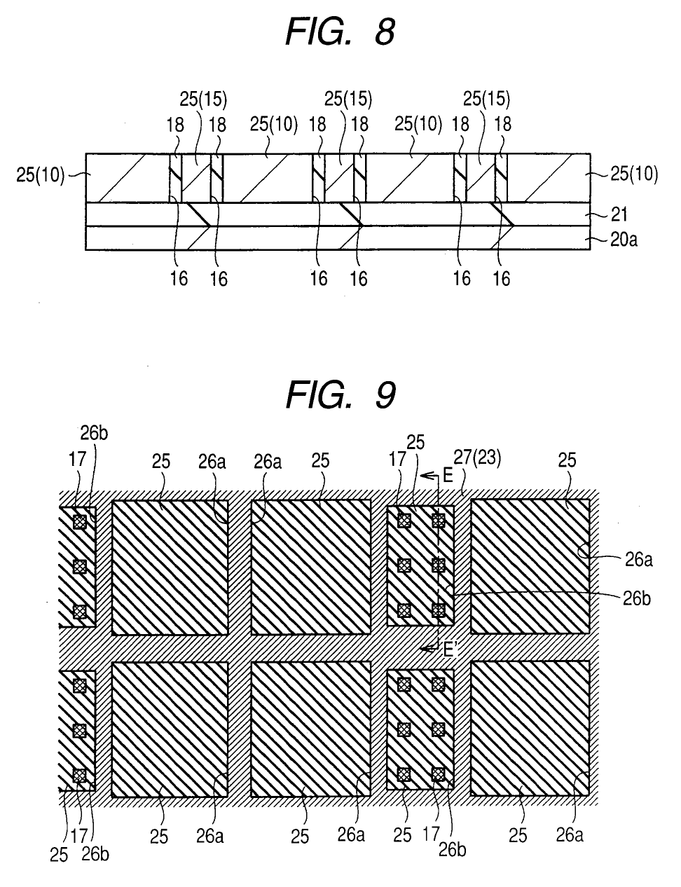

Successively, as shown in FIG. 8, an unnecessary portion of the insulating film 18 formed on the conductor layer 25 is removed, for example, by polishing using CMP (Chemical Mechanical Polishing). Thus, the insulating film 18 can be buried only in the inside of the hole 16 formed in the conductor layer 25.

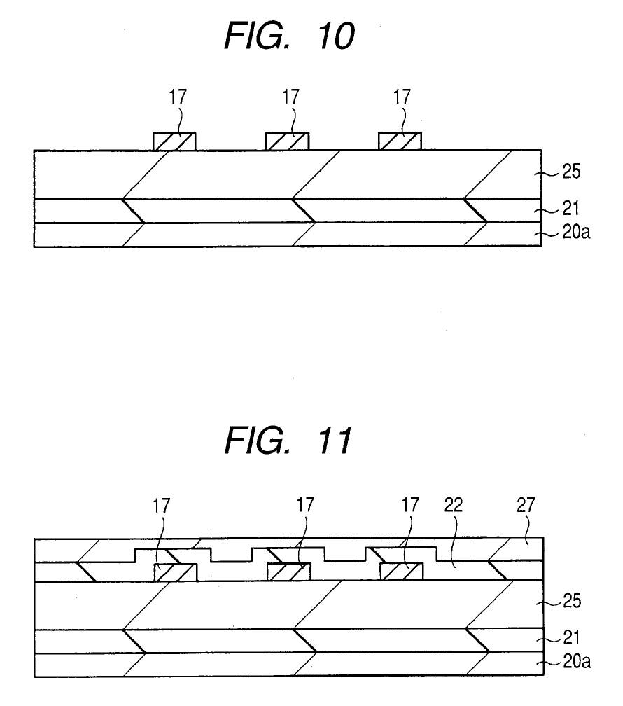

Then, after burying the insulating film 18 in the hole 16, a plurality of terminals 17 are formed on the conductor layer 25 as shown in FIG. 9. Then, an insulating film 22 (not illustrated in FIG. 9) is formed on the conductor layer 25, and a polysilicon film 27 is formed on the insulating film 22. Then, the polysilicon film 27 is patterned by using a photolithographic technique and an etching technique to form an opening 26a and an opening 26b. In the opening 26a and the opening 26b, the polysilicon film 27 and the insulating film 22 (not illustrated in FIG. 9) are removed to expose the conductor layer 25. The opening 25a corresponds to the device forming region and the opening 26b corresponds to the terminal forming region (external region). A plurality of terminals 17 are formed on the conductor layer 25 exposed from the opening 26b. The steps explained so far with reference to FIG. 9 are to be described using a cross sections (FIG. 10 to FIG. 12) along line E-E′ in FIG. 9.

As shown in FIG. 10, after forming an aluminum film on the conductor layer 25 using, for example, a sputtering method, the aluminum film is patterned by using a photolithographic technique and an etching technique. Patterning is conducted so as to form a plurality of terminals 17 in the outer region formed to the outside of the device forming region. That is, a plurality of terminals 17 each comprising an aluminum film are formed in the outer region.

Successively, as shown in FIG. 11, an insulating film 22 is formed over the entire surface of the conductor film 25 formed with the terminals 17. The insulating film 22 is formed, for example, of a silicon oxide film and can be formed, for example, by using a CVD method. Then, a polysilicon film 27 is formed on the insulating film 22. The polysilicon film 27 can be formed, for example, by using a CVD method.

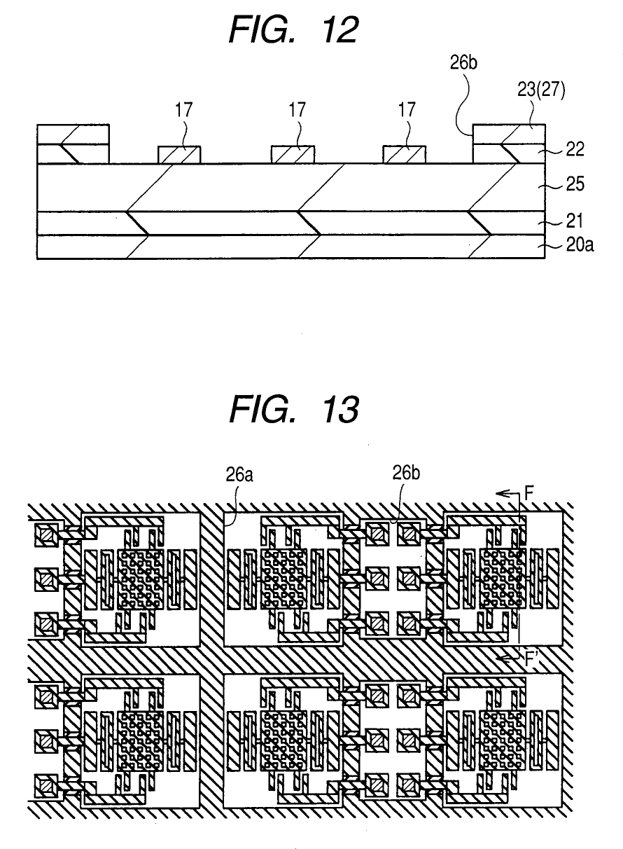

Then, as shown in FIG. 12, the insulating film 22 and the polysilicon film 27 formed above the conductor layer 25 are patterned by using a photolithographic technique and an etching technique. The patterning is conducted by opening the device forming region to form an opening 26a (not illustrated in FIG. 12. Refer to FIG. 9) and opening the terminal forming region (external region) to form an opening 26b. In the opening 26a and the opening 26b, the insulating film 22 and the polysilicon film 27 are removed to expose the conductor layer 25. In this step, in the regions other than the opening 26a and the opening 26b, the insulating film 22 and the polysilicon film 27 remain to form a base 23 comprising the polysilicon film 27. That is, the base 23 is formed in a region where the polysilicon film 27 remains, while the opening 26a and the opening 26b are formed in a region where the polysilicon film 27 does not remain. As described above, the structure shown in FIG. 9 can be formed.

In the first embodiment, after forming the terminal 17 on the external region of the conductor layer 25, the insulating film 22 is formed. However, this is not limitative and, after forming the insulating film 22 on the conductor layer 25, an opening may be formed in the external region and the terminal 17 may be formed on the conductor layer 25 exposed from the opening. In this case, after forming the terminal 17, the polysilicon film 27 is deposited and patterned to form the base 23 and open the external region where the terminal 17 is formed. Further, while the polysilicon film 27 is formed on the insulating film 22 in the first embodiment, it may be also constituted to form an amorphous silicon film instead of the polysilicon film 27.

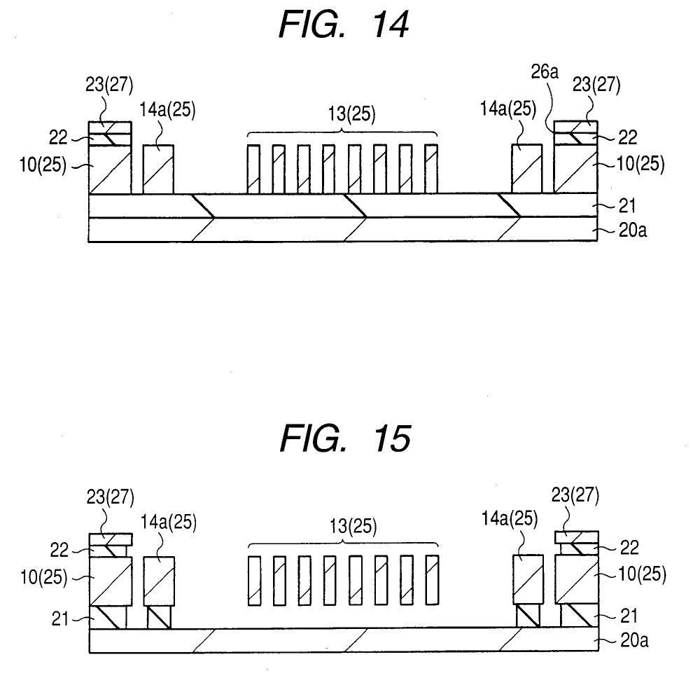

Then, as shown in FIG. 13, a structural body of the MEMS device is formed by patterning the conductor layer 25 exposed from the opening 26a where the device forming region is opened and the opening 26b where the terminal forming region (external region) is opened. The step is to be described with reference to the cross sectional views showing the cross section of FIG. 13 along line F-F′ (FIG. 14, FIG. 15).

As shown in FIG. 14, the conductor layer 25 exposed from the opening 26a is patterned by using the photolithographic technique and the etching technique. Thus, the base support 10, the fixed electrode 14a, and the movable portion 13 are formed. Although not illustrated in FIG. 14, the fixed portion 11, the beam 12, the movable electrode 14b, and the interconnection 15 shown in FIG. 1 are also formed by patterning the conductor layer 25. As described above, the structural body of the MEMS device can be formed from an identical conductor layer 25. In the first embodiment, since the structural body of the MEMS device is entirely formed from the identical conductor layer 25, the manufacturing step can be simplified compared with a case of forming the same with separate layers by separate steps.

Successively, as shown in FIG. 15, the movable portion 13 is suspended in the space by removing the intermediate insulative layer 21 formed in the layer below the movable portion 13 by etching. By the step, the movable portion 13 capable of moving can be formed. Although not illustrated in FIG. 15, the intermediate insulating film 21 formed in the layer below the beam 12 is also eliminated as shown in FIG. 4 and the beam 12 is also suspended in the space. The intermediate layer 21 formed in the layer below other structural body is not removed. This can fix the structural body other than the movable portion 13 and the beam 12 by way of the intermediate insulative layer 21 to the support substrate 20a.

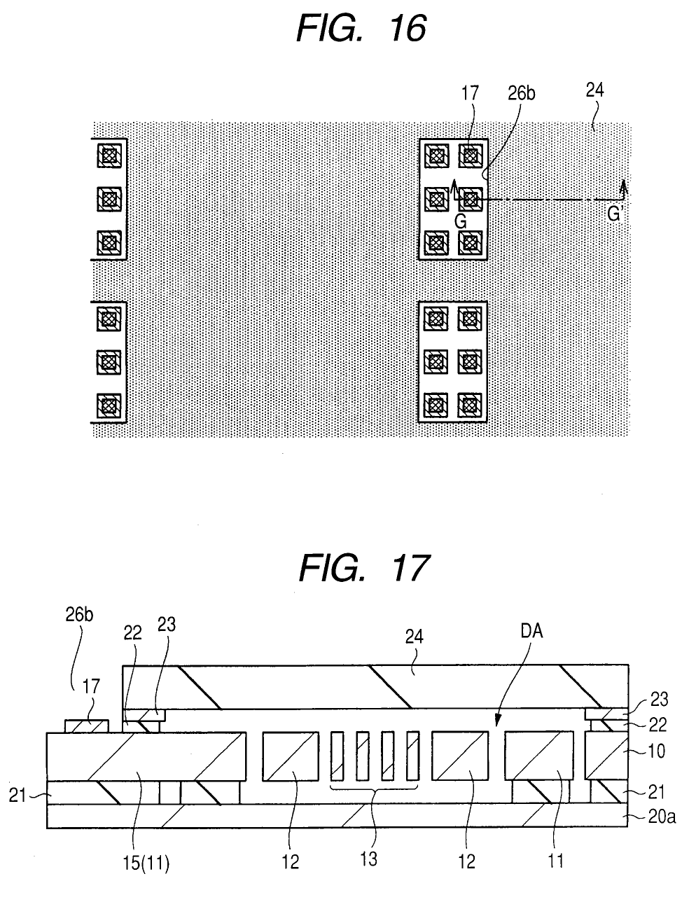

Then, as shown in FIG. 16, a cap 24 having predetermined openings are mounted above the MEMS structural body. In this case, predetermined openings are positioned so as to superpose above the openings 26b where a plurality of terminals 17 are formed. That is, a plurality of terminals 17 are exposed from the predetermined openings formed in the cap 24. Thus, even after forming the cap 24, portions above the terminals 17 can be opened and the terminals 17 can be electrically connected with an external integrated circuit by using wires and the like. FIG. 17 is a cross sectional view of FIG. 16 taken along line G-G′. As shown in FIG. 17, the cap 24 is formed so as to be bonded with the base 23 formed above the base support 10 by way of the insulating film 22. The cap 24 is formed so as to cover the device forming region DA, and the device forming region DA where the structural body of the MEMS device is formed is hermetically sealed by the cap 24. On the other hand, the opening of the cap 24 is formed to a portion above the terminal 17 in the external region. The external region where the terminal 17 is formed is a not hermetically sealed region different from the device forming region DA. The terminal 17 formed in the external region and the structural body formed in the inside of the device forming region DA are connected by the interconnection 15 extending from the device forming region DA to the external region.

In this case, as shown in FIG. 16, a plurality of terminals 17 are formed to the MEMS device, and sealed by the cap 24 that is opened so as to contain such a plurality of terminals 17 in common. For example, in a case of an angular velocity sensor or a combined sensor capable of simultaneously measuring the angular velocity and acceleration having a number of terminals 17, the terminals 17 are formed densely and portions above the terminals 17 formed densely can be sealed by the cap 24 that opens so as to include a plurality of terminals 17 in common. This can reduce the size of the MEMS device compared with a sealing method of forming through holes on every terminals and leading out the wiring. Further, the fabrication cost for the cap can also be decreased.

That is, in a case of the structure as shown in FIG. 41, since the electrode support 503 corresponding to the terminal is in a hermetically sealed space, it is difficult to dispose the opening in the cap 505 for hermetic seal thereby opening the portion above the plurality of electrode support 503. Accordingly, in a case of the structure as shown in FIG. 41, it is necessary to dispose through holes 506 in the cap 505 and form leading wirings on every electrode supports 503. That is, it is necessary to dispose the through hole 506 on every one of the plurality of electrode supports 503 and it is difficult to narrow the distance between a plurality of electrode supports 503. Particularly, the through hole 506 formed by sand blasting has a larger diameter at the surface of the cap 505 where the fabrication is started and a smaller diameter at the bottom thereof. Accordingly, it is necessary to determine the pitch between the through holes 506 corresponding to the hole diameter formed at the surface, which is disadvantageous for the reduction of size. Further, in the angular velocity sensor, the acceleration sensor and the combined sensor capable of simultaneously measuring various physical amounts such as angular velocity and acceleration, the number of required electrodes increases to impose a limit on the size reduction of the sensor by the size of the electrode.

On the contrary, in the cap 24 of the first embodiment, an opening is formed such that a plurality of terminals 17 are opened collectively. That is, the opening is formed such that the portion above the regions containing a plurality of terminals 17 are opened collectively. This is one of the features of the invention. The plurality of terminals 17 can be collectively opened in the cap 24 as described above, because the plurality of terminals 17 are formed not in the hermetically sealed device forming region DA but formed in the not sealed external region to the outside of the device forming region DA. That is, since the terminal 17 is formed in the external region, even when the opening that opens the portion above the terminal 17 is formed to the cap 24, this gives no undesired effects at all on the hermetic seal. With the reasons described above, the cap 25 having the opening above the terminal 27 can be used. Particularly, in the first embodiment, the openings formed in the cap 24 collectively open the regions above the plurality of terminals 17. With such a constitution, the size of the MEMS device can be decreased. That is, in the first embodiment, since the through holes are not formed on every terminal, it is not necessary for taking consideration on the hole size of the through hole and the distance between the plurality of terminals 17 can be narrowed. Accordingly, the size of the MEMS device can be decreased. Further, in the first embodiment, since the openings are not formed on every terminal 17, it has a merit capable of facilitating the fabrication for the cap 24. this can decrease the manufacturing cost for the MEMS device.

In the first embodiment, the cap 24 is formed, for example, of a glass substrate. This enables anodic bonding between the base 23 comprising the polysilicon film and the cap 24 comprising the glass substrate. As a result, sealing at a wafer level is possible. Since the cap 24 can be anodically bonded with the base 23, the structural body including the movable portion 13, the beam 12, the fixed portion 11, the detection portion 14, and a portion of the interconnection 15 can be sealed hermetically. Accordingly, the space for containing the structural body of the MEMS device can be put to a vacuum or gas atmosphere at a specified pressure. This can control the resistance due to the viscosity of a gas present in the space for containing the structural body of the MEMS device, for example, in the movement of the movable portion 13 and the movement of the movable electrode 14b for measuring the amount of displacement of the movable portion 13.

Further, in the first embodiment, while the glass substrate is used for the gap 24, a substrate of other materials such as a silicon substrate may also be used. Further, while an example of bonding the cap 24 and the base 23 by anodic bonding is shown as the bonding method, the cap 24 and the base 23 may also be bonded by using a normal temperature bonding using surface activation by plasmas or ions, or by using an adhesive such as a glass frit or solder.

For example, the cap 24 and the base 23 comprising the polysilicon film can be bonded by normal temperature bonding using a silicon substrate for the cap 24. In this case, since the cap 24 and the base 23 are formed of an identical material and sealing distortion caused by the difference of the temperature expansion coefficient between each of the sealing materials can be eliminated, an MEMS device of high performance can be obtained.

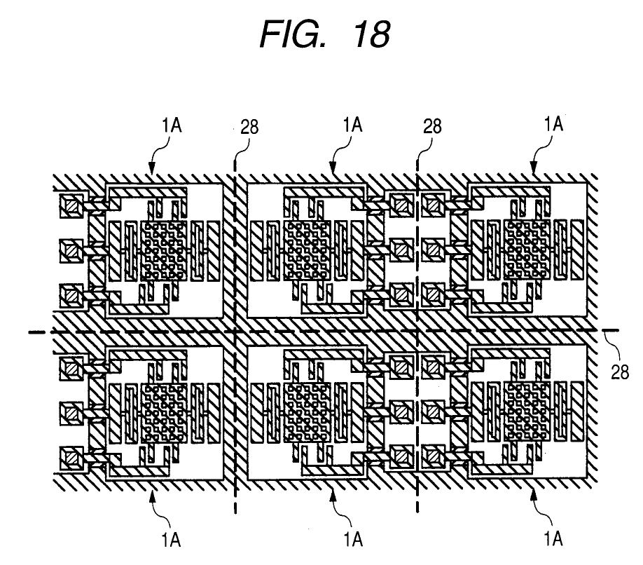

Then, as shown in FIG. 18, the MEMS devices 1A are individualized by dicing the semiconductor substrate bonded with the cap 24 along a dicing line (not illustrated in FIG. 18). Thus, the MEMS device 1A in the first embodiment can be formed. According to the first embodiment, electric signals from the structural body can be taken out externally by sealing the structural body of the MEMS device in a closed atmosphere and providing terminals electrically connected with the structural body to the outside of the hermetically sealed device forming region. According to the technique, since it is no more necessary to provide the through hole to the cap for sealing, and the bonded portion between the base surrounding the structural body and the cap can be made to a relatively larger area, it provides an advantage that the airtightness is not deteriorated with time and the reliability is excellent.

### Second Embodiment

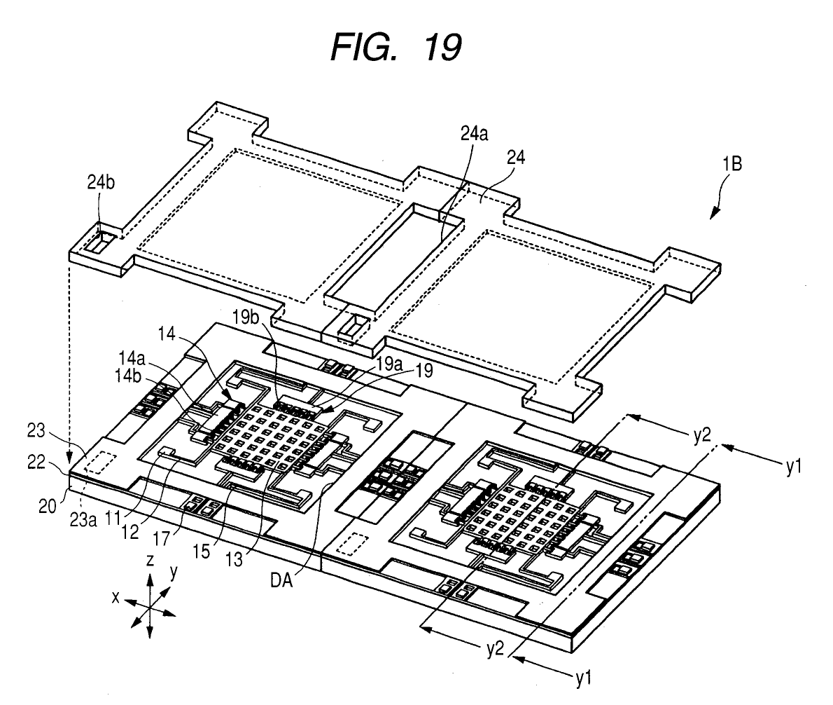

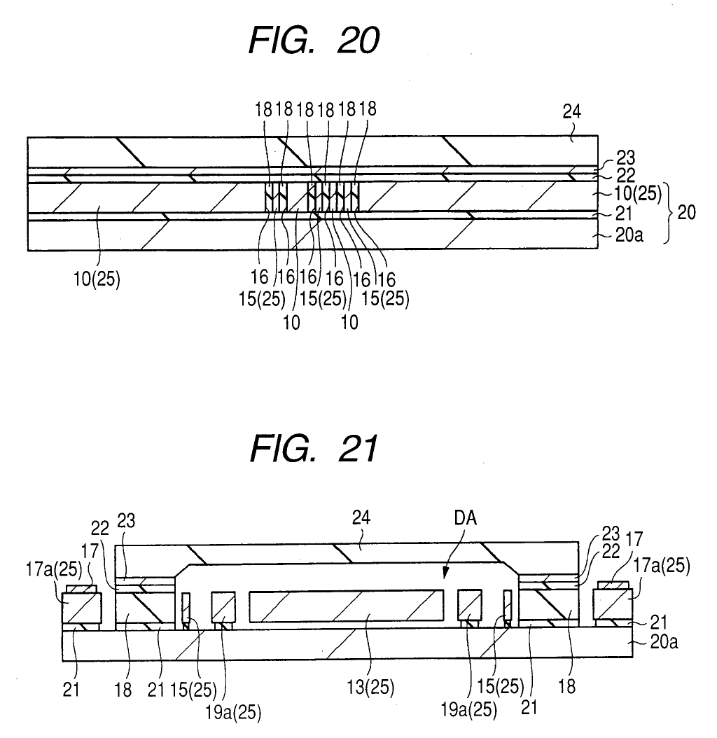

An MEMS device in a second embodiment is to be described with reference to the drawings. In the second embodiment, description is to be made to an angular velocity sensor as an example of the MEMS device. FIG. 19 is a perspective view showing main constitutional elements of the angular velocity sensor in the second embodiment in view of plane. FIG. 20 shows a cross section of FIG. 19 taken along line y1-y1 and FIG. 21 shows a cross section of FIG. 19 taken along line y2-y2.

In FIG. 19, a base 23 is formed by way of an insulating film 22 above a semiconductor substrate 20 comprising an SOI substrate by way of an insulating film 22, and an opening is formed in a device forming region DA surrounded with the base 23. The structural body of an MEMS device 1B is formed in the opening as the device forming region DA. For example, a fixed portion 11 and a beam 12 connected with the fixed portion 11 are formed to the inside of the device forming region DA, and a movable portion 13 as a mass body is formed by way of the beam 12. While the fixed portion 11 is fixed to the semiconductor substrate 20, the beam 12 and the movable portion 13 are not fixed to the semiconductor substrate 20 but are suspended in the space and can be displaced.

Further, a driving portion 19 for generating standard vibrations (excited vibrations) to the movable portion 13 is formed in the device forming region DA. The movable portion 19 comprises a fixed electrode 19a fixed to the semiconductor substrate 20 and a movable electrode 19b formed integrally with the movable portion 13. Further, a detection portion 14 for detecting the displacement of the movable portion 13 is formed in the device forming region DA. The movable portion 14 comprises a fixed electrode 14a fixed to the semiconductor substrate 20 and a movable electrode 14b formed integrally with the movable portion 13.

Interconnections 15 are led out respectively from the structural bodies formed in the device forming region DA and interconnections 15 extend from the device forming region DA to the external region at the outside, and connected electrically with terminals 17 in the external region. That is, the interconnections 15 penetrate the layer below the base 23 surrounding the device forming region DA and extend to the external region.

Successively, a cap 24 formed, for example, of a glass substrate is formed so as to seal the device forming region DA. The cap 24 is constituted so as to cover the device forming region DA and is bonded anodically on the base 23 with the base 23 formed, for example, of a polysilicon film. This can seal the device forming region DA. On the other hand, the cap 24 extends from the device forming region DA to the region at the outside and opens the portion above the external region formed with the terminal 17. That is, an opening 24a is formed in the cap 24. Further, an opening 24b is formed to the cap 24. That is, the base 23 is formed so as to surround the device forming region DA and extend from the device forming region DA to the outer side. Then, an electrode 23a for anodic bonding is formed to the base 23 formed so as to extend from the device forming region DA to the outer side. In this case, the cap 24 is formed while extending to a portion above the electrode 23a for anodic bonding, and the opening 24b is formed in the cap 24 above the electrode 23a for anodic bonding. That is, the base 23 is exposed from the opening 24b of the cap 24, and the exposed base 23 functions as an electrode 23a for anodic bonding. This is one of the features of the invention. By providing the opening 24b to the cap 24 to expose the base 23, it is possible to mount the cap 24 and then apply an electric voltage to the base 23 (electrode 23a for anodic bonding) exposed from the opening 24b, and the base 23 and the cap 24 can be anodically bonded easily.

FIG. 20 is a cross sectional view showing a cross section of FIG. 19 taken along line y1-y1. In FIG. 20, a semiconductor substrate 20 comprising an SOI substrate is formed of a support substrate 20a, an intermediate insulative layer 21 formed on the support substrate 20a, and a conductor layer 25 formed on the intermediate insulative layer 21. An insulating film 22 is formed on the conductor layer 25, and a base 23 is formed on the insulating film 22. Further, a cap 24 is formed on the base 23.

The conductor layer 25 is patterned to form a base support 10 and an interconnection 15. That is, the interconnection 15 is formed in the base support 10, and the interconnection 15 penetrates the base support 10. That is, the interconnection 15 extends from the device forming region DA surrounded with the base 23 formed on the base support 10 to the external region at the outside of the device forming region DA, and crosses the base support 10 formed in the layer below the base 23 in the course of extension to the external region. The cross section in the crossing region is shown in FIG. 20.

A hole 16 reaching the intermediate insulative layer 21 is formed between the crossing interconnection 15 and the base support 10 to prevent direct contact between the interconnection 15 and the base support 10. Then, an insulating film 18 is buried to the inside of the hole 16. Further, an insulating film 22 is formed on the base support 10, the interconnection 15, and the insulating film 18, and the base 23 is formed on the insulating film 22. As described above, the insulating film is formed so as to cover the periphery of the interconnection 15 in the crossing region between the interconnection 15 and the base support 10, to prevent occurrence of short-circuit between each of a plurality of interconnections 15.

FIG. 21 is a cross sectional view showing a cross section of FIG. 19 taken along line y2-y2. In FIG. 21, the intermediate insulative layer 21 is formed on the support substrate 20a, and the conductor layer 25 of the SOI substrate is formed on the intermediate insulative layer 21. The conductor 25 is patterned to form a terminal support 17a, the interconnection 15, the fixed electrode 19a and the movable portion 13. Further, while also the base support 10 is formed by patterning the conductor layer 25, the base support 10 is not illustrated in FIG. 21, and the insulating film 18 for burying the hole 16 disposed in the base support 10 is illustrated. An insulating film 22 is formed on the insulating film 18 (including the portion on the base support 10), and the base 23 is formed on the insulating film 22. The base 23 is bonded with the cap 24 and the device forming region DA is sealed by the cap 24. The terminal support 17a is formed to the outside of the sealed device forming region DA, and the terminal 17 is formed on the terminal support 17a.

The MEMS device 1B in the second embodiment is constituted as described above, and also the MEMS device 1B in the second embodiment has the same feature as the MEMS device 1A in the first embodiment. Accordingly, it can provide the same effect as that explained for the MEMS device 1A in the first embodiment.

For example, also in the second embodiment, the terminal 17 for external connection is disposed in the external region to the outside of the hermetically sealed device forming region DA. Accordingly, after attaching the cap 24 it is no more necessary to apply aperturing fabrication for forming terminal to the cap 24. This can suppress occurrence of micro-cracks to the bonded surface of the cap 24 to improve the airtightness. As a result, an MEMS device 1B of high performance and high reliability with less aging change such as pressure fluctuation can be formed.

Further, as shown in FIG. 20, by forming the hole 16 and forming the insulating films 18 to the hole 16, the interconnection 15 can be extended from the inside of the device forming region DA to the external region and the device forming region DA can be sufficiently sealed hermetically while ensuring the insulation property between the base support 10 and the interconnection 15.

Further, as shown in FIG. 21, it is one of the features of the invention that the cap 24 is not formed above the terminal 17 formed in the external region to the outside of the device forming region DA. That is, while the cap 24 extends as far as a portion above the terminal 17, it is previously formed with an opening for opening the portion above the terminal 17. This makes the aperturing fabrication for terminal connection to the cap 24 no more necessary and can simplify the manufacturing step of the MEMS device 1B.

While description has been made for the main effect, according to the second embodiment, the same effects as those in the first embodiment can also be obtained for other effects.

Then, the operation of the MEMS device 1B in the second embodiment is to be described. As shown in FIG. 19, by applying an appropriate voltage between the movable electrode 19b and the fixed electrode 19a of the driving portion 19, the movable portion 13 is always put to standard oscillation (excited oscillation) in the direction of axis y. When an angular velocity is applied in this state with respect to the axis z in FIG. 19, the beam 12 deforms elastically by Corioris force and the movable portion 13 displaces in the direction of the axis x perpendicular to the direction of the axis y where the movable portion 13 conducts standard vibrations. This changes the distance between the movable electrode 14b and the fixed electrode 14a of the detection portion 14. Accordingly, the static capacitance of the capacitor element constituted with the movable electrode 14b and the fixed electrode 14a changes. Angular velocity can be measured by detecting the change of the static capacitance by an external electric circuit or the like. Since the movable electrode 14b and the fixed electrode 14a are connected respectively by way of the interconnections 15 to the terminals 17, change of the static capacitance between the movable electrode 14b and the fixed electrode 14a can be measured by electrically connecting the terminal 17 to an integrated circuit for capacitance measurement separately from the MEMS device 1B. Further, an integrated circuit for measurement of the capacitance may be formed on one identical support substrate 20a with that for the MEMS device 1B and they may be electrically connected by using the terminal 17.

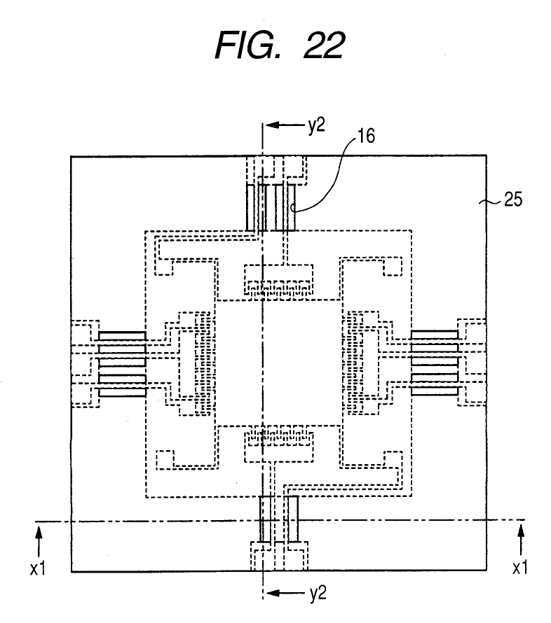

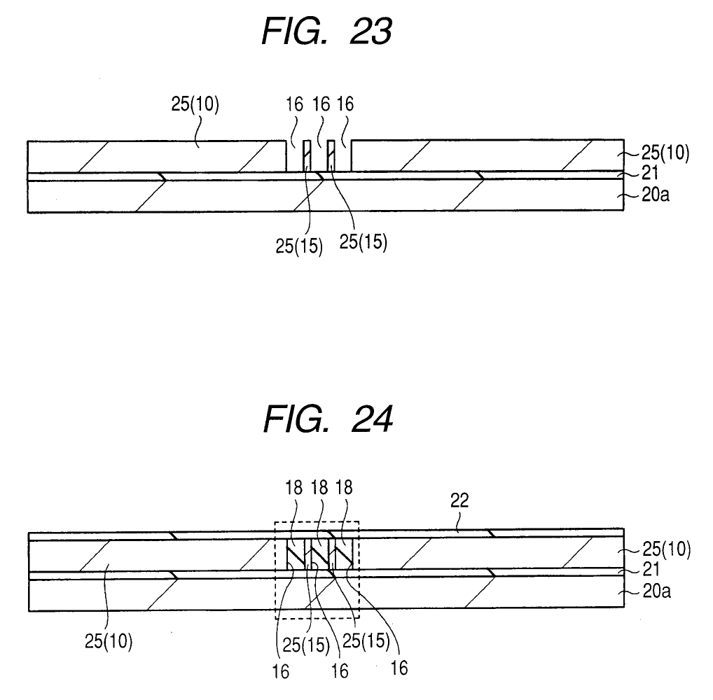

Successively, a method of manufacturing the MEMS device 1B in the second embodiment is to be described with reference to the drawings. At first, as shown in FIG. 22, holes 16 are formed to a conductor layer 25 of an SOI substrate by using photolithographic technique and etching technique. The constitution shown by broken lines in FIG. 22 shows a structural body formed in the steps to be described later and illustrated such that the position to form holes in the structural body can be seen. An insulation film is buried in the holes 16 after forming the holes 16 and the step is to be described with reference to a cross sectional view of FIG. 22 taken along line x1-x1 (FIG. 23, FIG. 24).

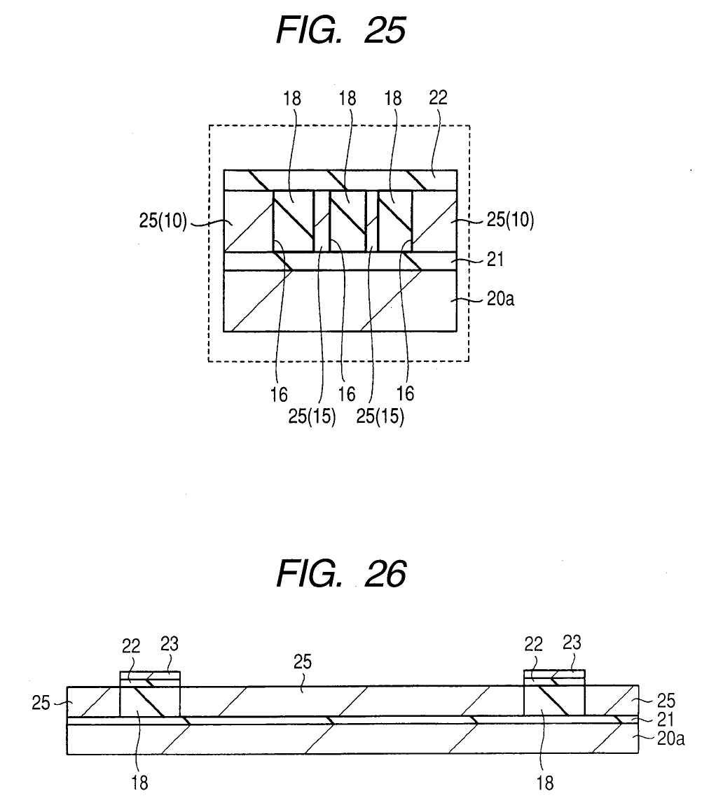

As shown in FIG. 23, an SOI substrate in which an intermediate insulative layer 21 is formed on a support substrate 25a, and a conductor layer 25 is formed on the intermediate insulative layer 21 is provided. Then, by using a photolithographic technique and an etching technique, the conductor layer 25 is etched to form holes 16 reaching the intermediate insulative layer 21. Then, as shown in FIG. 24, an insulating film 18 for burying the holes 16 and an insulating film 22 for covering the conductor layer 25 are formed, for example, by using a CVD method. The insulating film 18 and the insulating film 22 can be formed, for example, of a silicon oxide film. FIG. 25 is an enlarged cross sectional view of a region forming the hole 16 shown in FIG. 24.

Then, the step succeeding to FIG. 24 is to be described with reference to a cross sectional view of FIG. 22 taken along line y2-y2. As shown in FIG. 26, after forming a polysilicon film on the insulating film 22, the insulating film 22 and the polysilicon film are patterned by using a photolithographic technique and an etching technique. Patterning is conducted such that the insulating film 22 and the polysilicon film are left only in the region for forming a base 23. Thus, the base 23 comprising the polysilicon film can be formed.

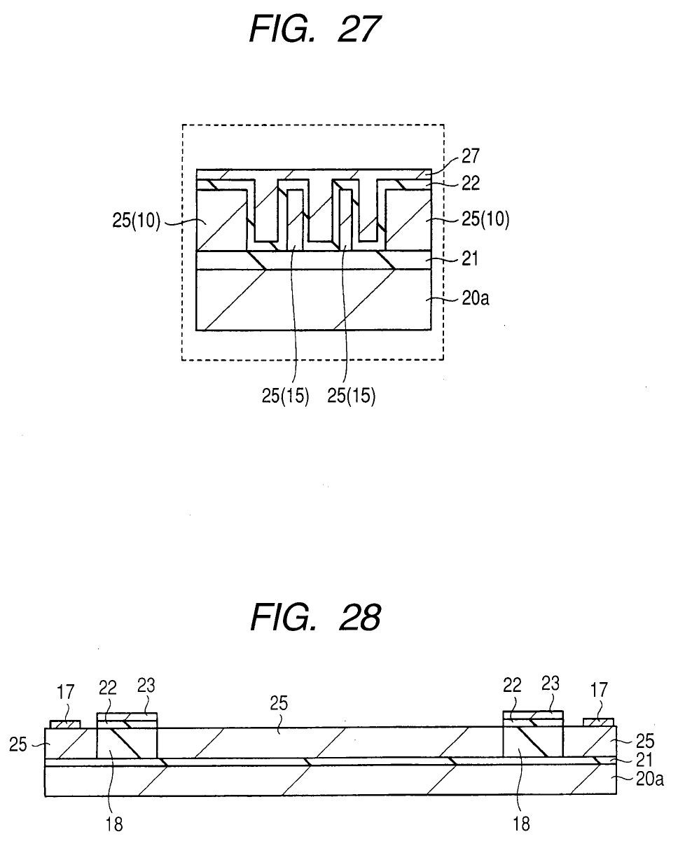

In this case, the base 23 may also be formed by the steps shown below. That is, as shown in FIG. 27 corresponding to FIG. 25, a thin insulating film 22 is formed to the surface of the hole 16 and the surface of the conductor layer 25 by using a thermal oxidation method or a CVD method. The insulating film 22 can be formed, for example, of a silicon oxide film or a silicon nitride film. Then, a polysilicon film 27 is formed on the insulating film 22 so as to bury the inside of the hole 16 with a silicon or polysilicon film 27 by using a film deposition technique such as a CVD method. Then, after planarizing the surface of the polysilicon film 27, a base 23 is formed by using a photolithographic technique and an etching technique. As described above, the hole 16 can be buried with the polysilicon film 27, and the base 23 can be formed on the insulating film 22. According to the method, as shown in FIG. 27, since the hole 16 is buried with the polysilicon film 27, the burying characteristic can be improved compared with the case of burying the hole 16 with the insulating film 18 as shown in FIG. 25. That is, by the polysilicon film 27, since the burying characteristics is better than the insulating film 18 such as a silicon oxide film, the hole 16 can be buried sufficiently. By using the method, after ensuring the insulation property for the hole 16 of several to several tens μm width by a thin silicon oxide film (insulating film 22) of about several hundreds nm, the hole 16 can be buried with the polysilicon film 27 capable of easily obtaining a film thickness of about several μm and it can be deposited on the insulating film 22 except for the hole 16.

Then, as shown in FIG. 28, an aluminum film is formed on the conductor layer 25 forming the base 23, for example, by a sputtering method. Then, the aluminum film is patterned by a photolithographic technique and an etching technique. Patterning is conducted so as to form a terminal 17 in an external region outside to the device forming region for forming a structural body of the MEMS device 1B.

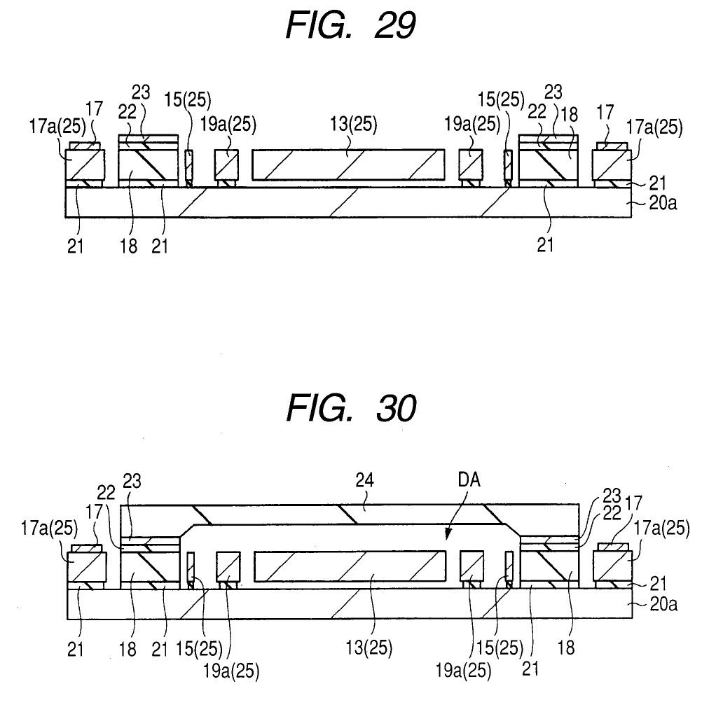

Successively, as shown in FIG. 29, the conductor layer 25 is patterned by using a photolithographic technique and an etching technique. Thus, an interconnection 15, a fixed electrode 19a, and a movable portion 13 are formed in the device forming region of the MEMS device 1B, and a terminal support 17a is formed in the external region outside to the device forming region. Although not illustrated in FIG. 29, the fixed portion 11, the beam 12, the driving portion 19 (movable electrode 19b), and the detection portion 14 (fixed electrode 14a, movable electrode 14b) shown in FIG. 19 are also formed by patterning the conductor layer 25. Then, the movable portion 13 can be made movable being suspended in the space by removing the intermediate insulative layer 21 formed in the layer below the movable portion 13. Although not illustrated in FIG. 29, the intermediate insulative layer 21 formed in the layer below the beam 12, the movable electrode 19b, and the movable electrode 14b is also removed, and such structural bodies can also be made movable being suspended in the space.

Then, as shown in FIG. 30, a cap 24 having predetermined openings and the fabricated SOI substrate are bonded. In this case, the base 23 and the cap 24 are anodically bonded in a state where the predetermined openings formed in the cap 24 are positioned such that they are disposed above the terminal forming region (external region). That is, the cap 24 is formed, for example, of a glass substrate. This can hermetically seal the device forming region DA, and open the external region positioned to the outside of the device forming region DA to expose the terminal 17.

Then, it is individualized into respective MEMS devices 1B by dicing. This can form the MEMS device 1B in the second embodiment. In the second embodiment, while a glass substrate is used for the cap 24, substrates with other materials such as a silicon substrate may also be used. Further, the bonding method is not restricted to the anodic bonding but bonding using an appropriate adhesive (glass frit, solder, etc.) or normal temperature bonding using surface activation by plasmas or ions may also be used.

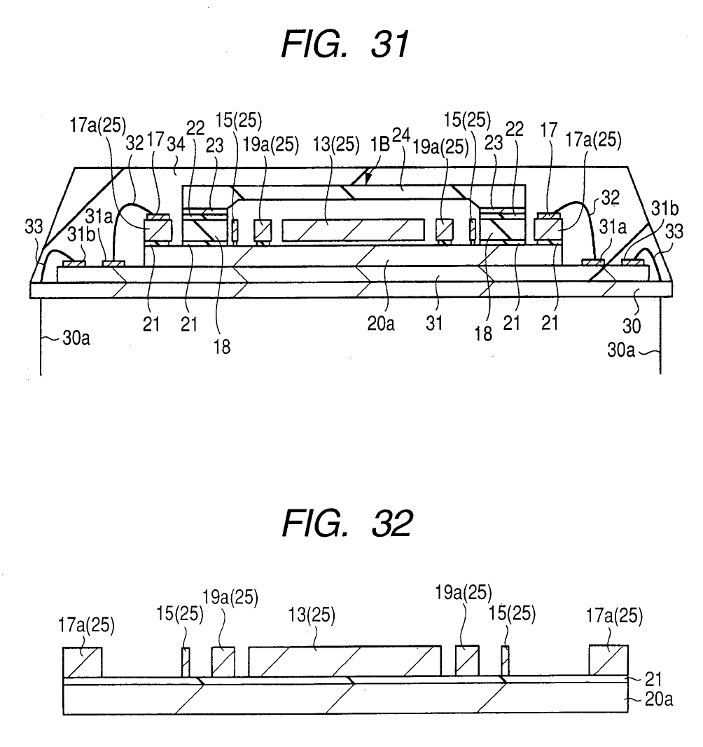

FIG. 31 shows an example of the mounting state of the MEMS device 1B manufactured by the steps described above. In FIG. 31, a signal processing IC 31 is formed on a lead 30, and the MEMS device 1B is mounted on the signal processing IC 31. Then, the terminal 17 formed to the MEMS device 1B and a terminal 31a formed to the signal processing IC 31 are electrically connected by a wire 32. Further, a terminal 31b on the signal processing IC 31 is electrically connected with the lead 30 by a wire 33. Further, a terminal 30a is formed to the lead 30. Then, the main surface of the lead 30, that is, the surface formed with the signal processing IC 31 and the MEMS device 1B is sealed with a resin 34. As described above, a semiconductor device mounting, for example, an angular velocity sensor can be obtained.

According to the second embodiment, electric signals from the structural body can be taken out to the outside by sealing the structural body of the MEMS device in a sealed atmosphere and by providing a terminal electrically connected with the structural body to the outside of the sealed device forming region. According to the technique, since the provision of a through hole in the sealing cap is no more necessary and the bonded portion between the base surrounding the structural body and the cap can be made to a relatively large area, it can provide an advantage that the airtightness is not degraded with time and the reliability is excellent.

### Third Embodiment

In the third embodiment, description is to be made to an angular velocity sensor as an example of the MEMS device 1B in the same manner as in the second embodiment. The constitution of the angular velocity sensor in the third embodiment is identical with the angular velocity sensor in the second embodiment. The difference is in the method of manufacturing the MEMS device 1B, and description is to be made for the third embodiment to an example of simultaneously conducting the formation of the hole 16 explained for the second embodiment and the formation of the structural body of the MEMS device 1B (fixed portion 11, beam 12, movable portion 13, detection portion 14, interconnection 15, and driving portion 19) collectively.

A method of manufacturing the MEMS device 1B in the third embodiment is to be described with reference to the drawings. The drawings used for the description use a cross sectional view showing a cross section of FIG. 22 taken along line y2-y2.

At first as shown in FIG. 32, an SOI substrate in which an intermediate insulative layer 21 is formed on a support substrate 20a and a conductor layer 25 is formed on the intermediate insulative layer 21 is provided. Then, the conductor layer 25 is patterned by using a photolithographic technique and an etching technique to form a terminal support 17a, an interconnection 15, a fixed electrode 19a, and a movable portion 13. The interconnection 15 is formed so as to electrically connect the movable portion 13 with the terminal support 17a, etc. Although not illustrated in FIG. 32, the fixed portion 11, the beam 12, the detection portion 14, and the driving portion 19 shown in FIG. 19 are also formed. Further, although not illustrated in FIG. 32, the base support 10 is also formed. Holes 16 formed in the base support 10 are also formed. In FIG. 32, a space is formed between the terminal support 17a and the interconnection 15 and the space contains an inner space of the hole 16.

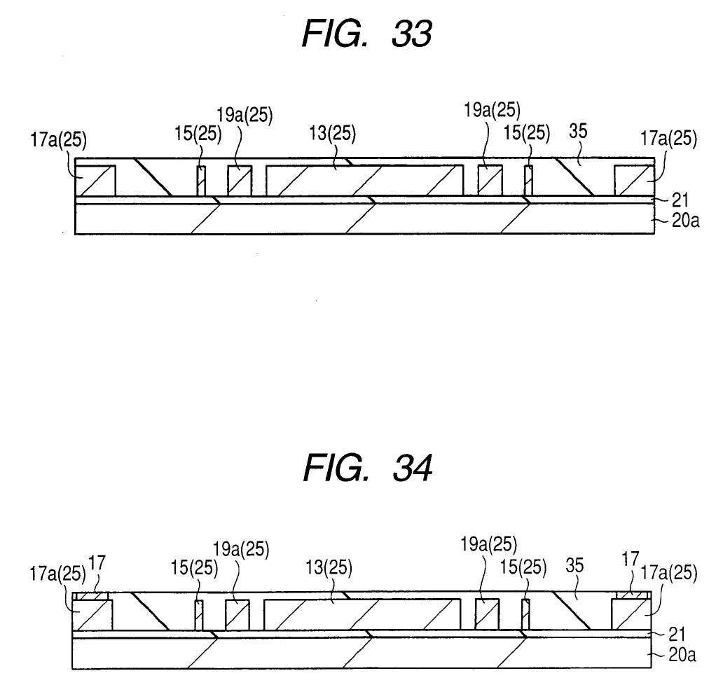

Then, as shown in FIG. 33, an insulating film 35 is formed so as to bury all the trenches formed in the conductor layer 25 containing an inner space of holes 16 (not illustrated in FIG. 33) and so as to cover the surface of the conductor layer 25. The insulating film 35 is formed, for example, of a silicon oxide film and can be formed by using, for example, a CVD method.

Successively, as shown in FIG. 34, holes are formed in the insulating film 35 by using a photolithographic technique and an etching technique. The holes are formed so as to expose terminal supports 17a. Then, a terminal 17 is formed on the terminal support 17a by forming, for example, an aluminum film on the insulating film 35 containing a portion on the terminal support 17a and by pattering the aluminum film. The terminal 17 is formed in the external region and disposed for electrical connection with a signal processing IC or a circuit pattern formed at the outside by means of a wire or the like.

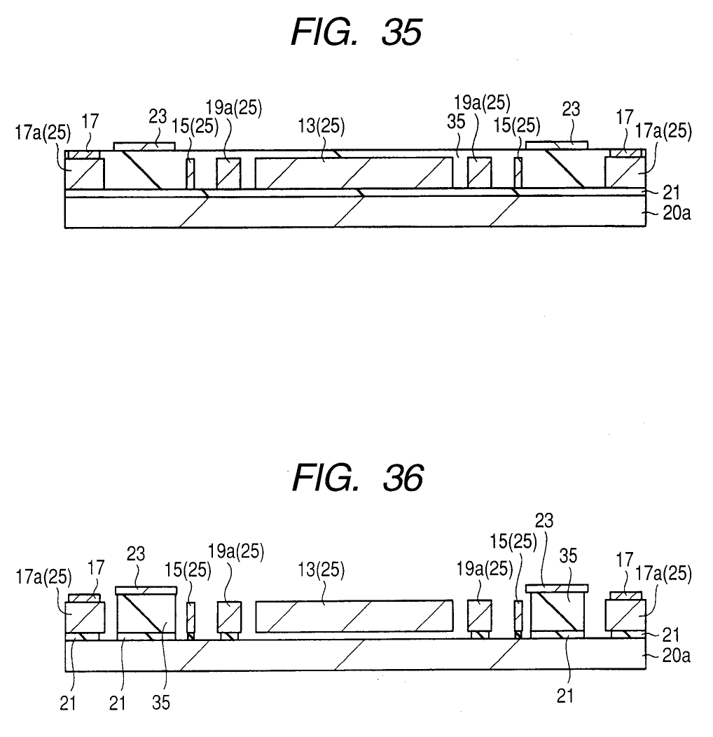

Then, as shown in FIG. 35, after depositing a silicon or polysilicon film, the polysilicon film is patterned by using a photolithographic technique and an etching technique. A base 23 is formed by the patterning. The base 23 is used as an electrode and a bonded surface upon surface bonding with a glass substrate (anodic bonding).

Successively, as shown in FIG. 36, the exposed insulating film 35 is removed by etching. In this case, the insulating film 35 formed below the base 23 is left. In this case, an inner space of the hole 16 (not illustrated in FIG. 36) is formed below the base 23 and the insulating film 35 buried in the inner space is shown in FIG. 36. Then, by removing the intermediate insulating film 21 formed in the layer below the movable portion 13, the movable portion 13 can be made movable being suspended in the space. Although not illustrated in FIG. 36, the intermediate insulative layer 21 formed in the layer below the beam 12, the movable electrode 19b, and the movable electrode 14b are also eliminated and the structural bodies can also be made movable being suspended in the space.

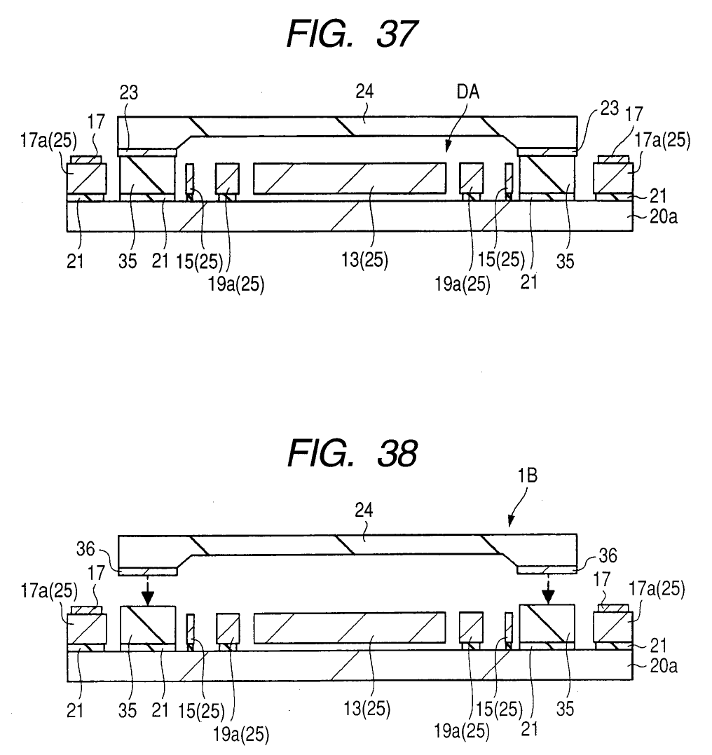

Then, as shown in FIG. 37, a cap 24 having predetermined openings and the fabricated SOI substrate are bonded. In this case, the base 23 and the cap 24 are anodically bonded in a state where the predetermined openings formed in the cap 24 are positioned such that they are disposed above the terminal forming region (external region). That is, the cap 24 is formed, for example, of a glass substrate. This can hermetically seal the device forming region DA, and open the external region positioned to the outside of the device forming region DA to expose the terminal 17. By conducting anodic bonding in a vacuum or gas atmosphere, the device forming region DA can be evacuated or put to a specific gas atmosphere.

Then, it is individualized into respective MEMS devices 1B by dicing. This can form the MEMS device 1B in the third embodiment. In the third embodiment, while the glass substrate is used for the cap 24, substrates with other materials such as a silicon substrate may also be used. Further, the bonding method is not restricted to the anodic bonding but bonding using an appropriate adhesive (glass frit, solder, etc.) or normal temperature bonding using surface activation by plasmas or ions may also be used.

According to the third embodiment, since hole 16 and the structural body formed in the conductor layer 25 such as the hole 16, the base support 10, the fixed portion 11, the beam 12, the movable portion 13, the detection portion 14, the interconnection 15, the terminal support 17a, and the driving portion 19 are fabricated collectively, the manufacturing step is simplified. As a result, the number of masks necessary for manufacturing the MEMS device 1B can be decreased to improve the production efficiency. Since other constitutions are identical with those in the second embodiment, the same effects as those of the second embodiment can be obtained.

### Fourth Embodiment

For the second embodiment, an example of bonding the SOI substrate and a cap by anodic bonding has been described. In the fourth embodiment, an example of bonding the SOI substrate and the cap by using a glass frit or an adhesive is to be described.

FIG. 38 is a cross sectional view showing a constitution of bonding an SOI substrate and a cap 24 by using an adhesive 36 such as a glass frit in the MEMS device 1B in the fourth embodiment. In FIG. 38, the MEMS device 1B in the fourth embodiment has substantially the same constitution as that of the MEMS device 1B in the second embodiment and different constitutions are to be described.

In the fourth embodiment, a base is not formed on the insulating film 35 (including a base support 10 (not illustrated in FIG. 38)), and the insulating film 35 and the cap 24 are bonded by means of an adhesive 36. The base is not disposed in this case by the reason shown below. In the second embodiment, the SOI substrate and the cap are bonded by anodic bonding. Therefore, a polysilicon film is necessary as a material for bonding with the cap comprising the glass substrate. Accordingly, a base comprising the polysilicon film is formed, and the base and the cap are anodically bonded. That is, the base is necessary for the anodic bonding. On the contrary, in the fourth embodiment, the SOI substrate and the cap 24 are intended to be bonded not by the anodic bonded but by using the adhesive 36. Therefore, provision of the base comprising the polysilicon film is not necessary.

According to the fourth embodiment, since sealing is conducted by using the adhesive 36, materials that can not be anodically bonded or bonded by surface activation at normal temperature can also be bonded to each other. As a result, the sealing material can be selected from a widened range to improve the production efficiency.

Since other constitutions in the fourth embodiment are identical with those in the second embodiment, the same effects as those of the second embodiment can be obtained.

### Fifth Embodiment

In the fifth embodiment, description is to be made to an example of an MEMS device in which electrical connection to the outside from the detection portion formed in the inside of the movable portion is possible in case where the detection portion or the like is formed in a region surrounded at the periphery such as the inside of the movable portion constituting the MEMS device is formed.

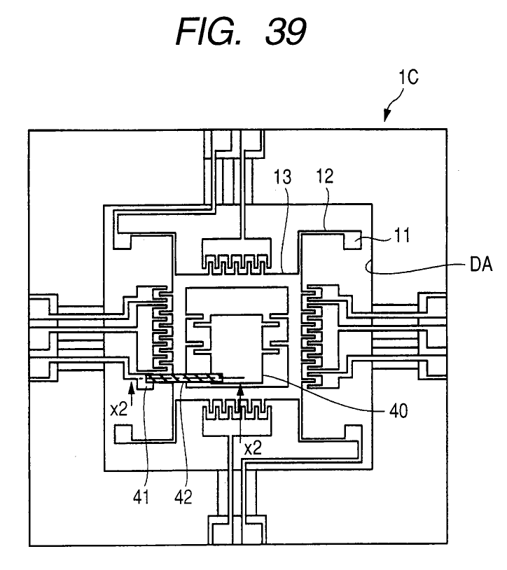

FIG. 39 is a plan view showing the constitution of an MEMS device IC in the fifth embodiment. As shown in FIG. 39, fixed portions 11 are formed to the inside of the hermetically sealed device forming region DA, and an elastically deformed beam 12 is connected to the fixed portion 11. Then, a movable portion 13 which is a mass portion and capable of displacement is formed to the beam 12. A detection portion 40 surrounded at the periphery is formed in the inside of the movable portion 13. It is adapted such that the displacement of the movable portion 13 is detected as capacitance change by the detection portion 40 and an angular velocity can be detected. That is, the static capacitance of a capacitor element formed between the movable electrode and the fixed electrode is changed by the change of the distance between the movable electrode formed integrally with the movable portion 13 and the fixed electrode formed to the detection portion 40 by the displacement of the movable portion 13, and the angular velocity can be detected by outputting the change of the static capacitance (voltage change, etc.) as an electric signal to a signal processing integrated circuit connected to the outside.

In this case, since the detection portion 40 is surrounded at the periphery thereof with the movable portion 13, electric signals by the detection portion 40 can not be taken out to the outside. Then, in the fifth embodiment, the detection portion 40 and the fixed electrode 41 formed to the outside of the movable portion 13 are connected by an aerial interconnection 42 disposed so as to override the movable portion 13. Thus, electric signals from the detection portion 40 surrounded at the periphery by the movable portion 13 can be outputted by way an aerial interconnection 42 to the fixed electrode 41 and, further, can be outputted from the fixed electrode 41 to the terminal formed to the outside of the device forming region DA. Since the aerial interconnection 42 does not connect the inside and the outside of the hermetically sealed device forming region DA, but is formed in the inside of the hermetically sealed device forming region DA, there is no problem upon sealing.

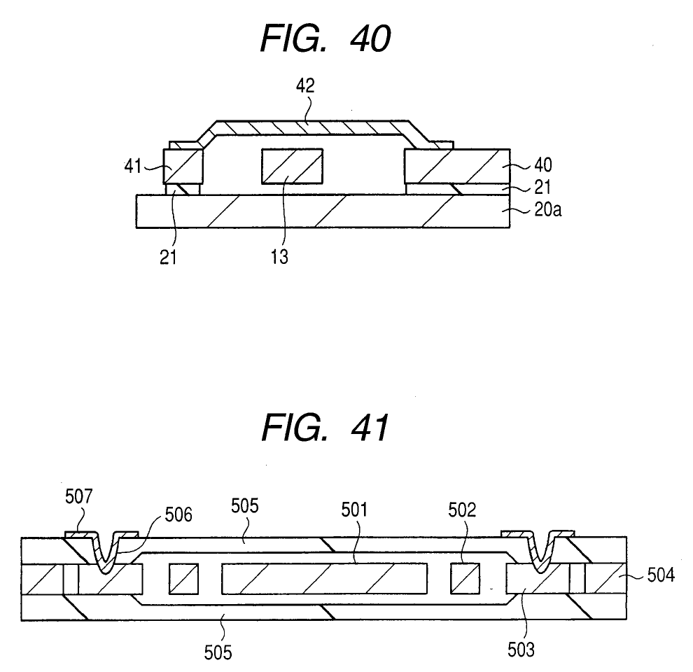

FIG. 40 is a cross sectional view showing a cross section of FIG. 39 taken along line x2-x2. The detection portion 40 is formed by way of the intermediate insulative layer 21 over a support substrate 20a. The detection portion 40 is fixed to the support substrate 20a by the intermediate insulative layer 21, and the movable portion 13 is formed to the outside of the detection portion 40. Further, the fixed electrode 41 is formed to the outside of the movable portion 13. Then, the aerial interconnection 42 is connected between the detection portion 40 and the fixed electrode 41 so as to override the movable electrode 13 to electrically connect the detection portion 40 and the fixed electrode 41. As described above, according to the fifth embodiment, also in a case where the detection portion 40 is present in a region surrounded at the periphery thereof with the movable portion 13, electric signals can be taken out to the outside from the detection portion 40 surrounded at the periphery by forming the aerial interconnection 42 so as to override the movable portion 13.

While the invention made by the present inventor has been described specifically with reference to the preferred embodiments, it will be apparent that the invention is not restricted to the embodiment described above and can be modified variously within a range not departing the scope of the gist thereof.

The present invention can be utilized generally in the manufacturing industry of manufacturing MEMS devices such as for acceleration sensors, angular velocity sensors, and combined sensors.

What is claimed is:

1. A micro-electromechanical systems device including:
(a) a semiconductor substrate,
(b) a base support fixed to the semiconductor substrate and formed so as to surround a predetermined region,
(c) a fixed portion fixed to the semiconductor substrate and formed within the predetermined region,
(d) a beam connected to the fixed portion and formed within the predetermined region,
(e) a movable portion connected to the beam and suspended in the space within the predetermined region,
(f) a terminal portion surrounded with the base support and formed to the outside of the predetermined region,
(g) an interconnection for connecting the movable portion and the terminal portion while penetrating the base support,
(h) a base formed above the base support and the interconnection and formed so as to surround the predetermined region, and
(i) a cap formed on the base and covering the predetermined region, in which an insulating film is formed between the base support and the interconnection and between the interconnection and the base.

2. The micro-electromechanical systems device according to claim 1, wherein
the insulating film is formed also between the base support and the base.

3. The micro-electromechanical systems device according to claim 1, wherein
the base support, the fixed portion, the beam, and the movable portion are formed by fabricating an identical conductor layer.

4. The micro-electromechanical systems device according to claim 1, wherein
the semiconductor substrate comprises a support substrate, an intermediate insulative layer formed on the support substrate, and a conductor layer formed on the intermediate insulative layer.

5. The micro-electromechanical systems device according to claim 4, wherein
the conductor layer is formed of a polysilicon film or a metal film.

6. The micro-electromechanical systems device according to claim 4, wherein
the base support, the fixed portion, the beam and the movable portion are formed by fabricating the conductor layer.

7. The micro-electromechanical systems device according to claim 1, wherein
the cap extends as far as a portion above the terminal portion and has an opening above the terminal portion.

8. The micro-electromechanical systems device according to claim 7, wherein
the terminal portion is present in plurality, and the openings formed to the cap are formed so as to open the portions above the region including the plural terminal portions.

9. The micro-electromechanical systems device according to claim 1, wherein
the cap is formed of one of a glass substrate, semiconductor substrate, or metal substrate.

10. The micro-electromechanical systems device according to claim 1, wherein
the base surrounds the predetermined region and extends from the predetermined region to the outside.

11. The micro-electromechanical systems device according to claim 10, wherein
an electrode portion for anodic bonding is formed to a portion of the base that extends from the predetermined region to the outside, the cap is formed being extended as far as the portion above the electrode portion for anodic bonding, and an opening is formed to the cap above the electrode portion for anodic bonding.

12. The micro-electromechanical systems device according to claim 1, wherein
the predetermined region is hermetically sealed.

13. A method of manufacturing a micro-electromechanical systems device including the steps of:
(a) providing a semiconductor substrate containing a support substrate, an intermediate insulative layer formed on the support substrate, and a conductor layer formed on the intermediate insulative layer,
(b) forming a hole reaching the intermediate insulative layer in the conductor layer,
(c) burying a first insulating film in the hole,
(d) forming a first conductor film on the conductor layer,
(e) patterning the first conductor film thereby forming a terminal portion to the outside of a predetermined region,
(f) forming a second insulating film on the conductor layer,
(g) forming a second conductor film on the second insulating film,
(h) patterning the second insulating film and the second conductor film thereby forming the predetermined region and a base for opening the terminal portion,
(i) patterning the conductor layer exposed to the predetermined region and the terminal portion, thereby forming a base support surrounding the predetermined portion and formed with the base at an upper portion thereof by way of the second insulating film, forming a fixed portion within the predetermined region, and further forming a beam connected to the fixed portion and formed in the predetermined region, a movable portion connected to the beam and formed within the predetermined region, and an interconnection for connecting the movable portion and the terminal portion, in which the first insulating film is formed between the interconnection penetrating the base support and the base support, and the second insulating film is formed between the interconnection penetrating the base support and the base,
(j) removing the intermediate insulative layer formed in the layer below the beam and the movable portion thereby suspending the movable portion in the space within the predetermined region, and
(k) bonding the base and the cap to seal the predetermined region.

14. A method of manufacturing a micro-electromechanical systems device including the steps of:
(a) providing a semiconductor substrate containing a support substrate, an intermediate insulative layer formed on the support substrate and a conductor layer formed on the intermediate insulative layer,
(b) patterning the conductor layer thereby forming a base support surrounding a predetermined region, a fixed portion formed within the predetermined region, a beam connected to the fixed portion and formed within the predetermined region, a movable portion connected to the beam and formed within the predetermined region and an interconnection extending from the predetermined region to the outside penetrating the base support,
(c) forming a third insulative layer so as to bury the patterned conductor layer, in which the third insulating film is formed to the periphery of the interconnection penetrating the base support,
(d) forming a terminal portion on the conductor film at the outside of the predetermined region and connecting the terminal portion and the interconnection,
(e) forming a base on the base support by way of the third insulating film,
(f) removing the third insulating film within the predetermined region and the intermediate insulating film formed in the layer below the beam and the movable portion, thereby suspending the movable portion in the space within the predetermined region, and
(g) bonding the base and the cap thereby sealing the predetermined region.

15. The method of manufacturing a micro-electromechanical systems device according to claim 13, wherein
the cap has an opening for opening a region above the terminal portion formed to the outside of the predetermined region.

16. The method of manufacturing a micro-electromechanical systems device according to claim 15, wherein
the opening in the cap opens the plural terminal portions collectively.

17. The method of manufacturing a micro-electromechanical systems device according to claim 13, wherein
the second conductor film is a polysilicon film.

18. The method of manufacturing a micro-electromechanical systems device according to claim 17, wherein
the cap is a glass substrate, and the base comprising the polysilicon film and the cap are bonded by anodic bonding.

19. The method of manufacturing a micro-electromechanical systems device according to claim 17, wherein
the cap is a silicon substrate and the base comprising the polysilicon film and the cap are bonded by normal temperature bonding.

20. The method of manufacturing a micro-electromechanical systems device according to claim 13, wherein
the step (c) is conducted by depositing the first insulating film using a chemical vapor deposition method.
